(19) United States
(12) Patent Application Publication
(10) Pub. No.: US 2025/0284867 A1
(43) Pub. Date: Sep. 11, 2025

(54) THERMODYNAMIC COMPUTING RELAY GADGET

(71) Applicant: Extropic Corp., Austin, TX (US)

(72) Inventors: Christopher Chamberland, Austin, TX (US); Guillaume Verdon-Akzam, Montreal (CA)

(73) Assignee: Extropic Corp., Austin, TX (US)

(21) Appl. No.: 18/598,877

(22) Filed: Mar. 7, 2024

(51) Int. Cl. G06F 30/28; G01R 33/035; H01H 61/01

(52) U.S. Cl. CPC G06F 30/28; G01R 33/0354; H01H 61/01

(57) ABSTRACT

A thermodynamic relay gadget includes a relay oscillator and an on-chip controller. The relay oscillator has a time dependent mass or time dependent frequency that is controllable, by the on-chip controller. The relay gadget is configured to relay thermodynamic information in analog form between an output oscillator of a first energy-based model and an input oscillator of a second energy-based model.

### BACKGROUND

Various algorithms, such as machine learning algorithms, often use statistical probabilities to make decisions or to model systems. Some such learning algorithms may use Bayesian statistics, or may use other statistical models that have a theoretical basis in natural phenomena. Also, machine learning algorithms themselves may be implemented using Bayesian statistics, or may use other statistical models that have a theoretical basis in natural phenomena.

Generating such statistical probabilities may involve performing complex calculations which may require both time and energy to perform, thus increasing a latency of execution of the algorithm and/or negatively impacting energy efficiency. In some scenarios, calculation of such statistical probabilities using classical computing devices may result in non-trivial increases in execution time of algorithms and/or energy usage to execute such algorithms.

As an alternative, algorithms may be performed using thermodynamic computers. However, communication between multiple algorithms implemented on a thermodynamic computing device and/or communications between thermodynamic computing devices may require converting information into a classical computing device form, thus reducing at least some of the benefits of a thermodynamic computer implementation.

### BRIEF DESCRIPTION OF THE DRAWINGS

FIG. 1A is high-level diagram illustrating a first energy-based model (EBM) implemented using a thermodynamic chip, a second energy-based model (EBM) implemented using a thermodynamic chip, and a relay gadget implemented using a thermodynamic chip, wherein the relay gadget is configured to relay thermodynamic information between the first energy-based model (EBM) and the second energy-based model (EBM), according to some embodiments.

FIG. 1B is high-level diagram similar to FIG. 1A, wherein the relay gadget does not include a bias oscillator, according to some embodiments.

FIG. 2A is a high-level flowchart illustrating a process of relaying thermodynamic information between an output oscillator, such as of a first energy-based model (EBM), and an input oscillator, such as of a second energy-based model (EBM), according to some embodiments.

FIG. 2B is a high-level flowchart illustrating a process similar to FIG. 2A, wherein the process of relaying the thermodynamic information does not require the use of a bias oscillator, according to some embodiments.

FIG. 3A is a diagram illustrating hardware components that may be used to implement oscillators of the first and second energy-based models (EBMs), as well as two different example hardware configurations of a relay oscillator that have a time-dependent mass or a time-dependent frequency, respectively, according to some embodiments.

FIG. 3B is a diagram illustrating hardware components similar to FIG. 3A, wherein the relay gadget does not include a bias oscillator, according to some embodiments.

FIG. 4 is a diagram providing additional details regarding a hardware configuration used to implement a relay oscillator with a time-dependent frequency, according to some embodiments.

FIG. 5 is a diagram providing additional details regarding a hardware configuration used to implement a relay oscillator with a time-dependent mass, according to some embodiments.

FIG. 6A is a conceptual diagram illustrating relative masses and frequencies of oscillators of the first energy-based model (EBM), relative masses and frequencies of oscillators of the second energy-based model (EBM), and relative masses and frequencies of oscillators of the relay gadget, at an initial stage of a relay process, prior to coupling the relay oscillator to the output oscillator of the first energy-based model (EBM), according to some embodiments.

FIG. 6B is a conceptual diagram illustrating relative masses and frequencies of oscillators of the first energy-based model (EBM), relative masses and frequencies of oscillators of the second energy-based model (EBM), and relative masses and frequencies of oscillators of the relay gadget, at a subsequent stage of a relay process, wherein coupling is activated between the relay oscillator and the output oscillator of the first energy-based model (EBM), according to some embodiments.

FIG. 6C is a conceptual diagram illustrating relative masses and frequencies of oscillators of the first energy-based model (EBM), relative masses and frequencies of oscillators of the second energy-based model (EBM), and relative masses and frequencies of oscillators of the relay gadget, at another stage of a relay process, wherein coupling is activated between the relay oscillator and the bias oscillator of the relay gadget, and wherein the mass of the relay oscillator is increased, according to some embodiments.

FIG. 6D is a conceptual diagram illustrating relative masses and frequencies of oscillators of the first energy-based model (EBM), relative masses and frequencies of oscillators of the second energy-based model (EBM), and relative masses and frequencies of oscillators of the relay gadget, at a next stage of a relay process, wherein coupling is activated between the relay oscillator and the input oscillator of the second energy-based model (EBM), according to some embodiments.

FIG. 7A is a conceptual diagram illustrating relative masses and frequencies of oscillators of the first energy-based model (EBM), relative masses and frequencies of oscillators of the second energy-based model (EBM), and relative masses and frequencies of oscillators of the relay gadget, at an initial stage of a relay process, prior to coupling the relay oscillator to the output oscillator of the first energy-based model (EBM), according to some embodiments.

FIG. 7B is a conceptual diagram illustrating relative masses and frequencies of oscillators of the first energy-based model (EBM), relative masses and frequencies of oscillators of the second energy-based model (EBM), and relative masses and frequencies of oscillators of the relay gadget, at a subsequent stage of a relay process, wherein coupling is activated between the relay oscillator and the output oscillator of the first energy-based model (EBM), according to some embodiments.

FIG. 7C is a conceptual diagram illustrating relative masses and frequencies of oscillators of the first energy-based model (EBM), relative masses and frequencies of oscillators of the second energy-based model (EBM), and relative masses and frequencies of oscillators of the relay gadget, at another stage of a relay process, wherein the mass of the relay oscillator is increased, according to some embodiments.

FIG. 7D is a conceptual diagram illustrating relative masses and frequencies of oscillators of the first energy-based model (EBM), relative masses and frequencies of oscillators of the second energy-based model (EBM), and relative masses and frequencies of oscillators of the relay gadget, at a next stage of a relay process, wherein coupling is activated between the relay oscillator and the input oscillator of the second energy-based model (EBM), according to some embodiments.

FIG. 8A is a conceptual diagram illustrating relative masses and frequencies of oscillators of the first energy-based model (EBM), relative masses and frequencies of oscillators of the second energy-based model (EBM), and relative masses and frequencies of oscillators of the relay gadget, at an initial stage of a relay process, prior to coupling the relay oscillator to the output oscillator of the first energy-based model (EBM), according to some embodiments.

FIG. 8B is a conceptual diagram illustrating relative masses and frequencies of oscillators of the first energy-based model (EBM), relative masses and frequencies of oscillators of the second energy-based model (EBM), and relative masses and frequencies of oscillators of the relay gadget, at a subsequent stage of a relay process, wherein coupling is activated between the relay oscillator and the output oscillator of the first energy-based model (EBM), according to some embodiments.

FIG. 8C is a conceptual diagram illustrating relative masses and frequencies of oscillators of the first energy-based model (EBM), relative masses and frequencies of oscillators of the second energy-based model (EBM), and relative masses and frequencies of oscillators of the relay gadget, at another stage of a relay process, wherein coupling is activated between the relay oscillator and the bias oscillator of the relay gadget, and wherein the frequency of the relay oscillator is tuned to adjust a value of the product of mass times frequency squared of the relay oscillator, according to some embodiments.

FIG. 8D is a conceptual diagram illustrating relative masses and frequencies of oscillators of the first energy-based model (EBM), relative masses and frequencies of oscillators of the second energy-based model (EBM), and relative masses and frequencies of oscillators of the relay gadget, at a next stage of a relay process, wherein coupling is activated between the relay oscillator and the input oscillator of the second energy-based model (EBM), according to some embodiments.

FIG. 9 is an example chart illustrating effects of coupling an output oscillator degree of freedom (e.g. position) to a relay oscillator degree of freedom (e.g. position), and subsequently coupling the relay oscillator degree of freedom to an input oscillator degree of freedom (e.g. position), wherein a mass of the relay oscillator is adjusted during the relay process, according to some embodiments.

FIG. 10 is an example chart illustrating effects of coupling an output oscillator degree of freedom (e.g. position) to a relay oscillator degree of freedom (e.g. position), and subsequently coupling the relay oscillator degree of freedom to an input oscillator degree of freedom (e.g. position), wherein a frequency of the relay oscillator is adjusted during the relay process, according to some embodiments.

FIG. 11A illustrates an example configuration, wherein the first energy-based model (EBM), the second energy-based model (EBM) and the relay gadget are implemented using oscillators of different thermodynamic chips, according to some embodiments.

FIG. 11B illustrates an example configuration similar to that of FIG. 11A, wherein the relay gadget does not include a bias oscillator, according to some embodiments.

FIG. 12A illustrates an example configuration, wherein the first energy-based model (EBM), the second energy-based model (EBM) and the relay gadget are implemented using oscillators of a single thermodynamic chip, according to some embodiments.

FIG. 12B illustrates an example configuration similar to that of FIG. 12A, wherein the relay gadget does not include a bias oscillator, according to some embodiments.

FIG. 13A illustrates example couplings between visible neurons of an energy-based model (EBM), according to some embodiments.

FIG. 13B illustrates example couplings between visible neurons and non-visible neurons (e.g., hidden neurons) of an energy-based model (EBM), according to some embodiments.

FIG. 14 is high-level diagram illustrating a process of determining weights and biases to be used in an energy-based model (EBM), wherein the weights and biases are determined using measurement values for synapse oscillators, according to some embodiments.

FIG. 15 is high-level diagram illustrating a process of determining weights and biases to be used in an energy-based model (EBM), wherein the weights and biases are computed using a classical computing device, according to some embodiments.

FIG. 16A is high-level diagram illustrating an example neuro-thermodynamic computer comprising a thermodynamic chip (e.g., that implements multiple energy-based models (EBMs) and a relay gadget) included in a dilution refrigerator and coupled to a classical computing device in an environment external to the dilution refrigerator, according to some embodiments.

FIG. 16B is high-level diagram illustrating an example neuro-thermodynamic computer comprising multiple thermodynamic chips (e.g., that implement respective energy-based models (EBMs) and a relay gadget) included in multiple dilution refrigerators and coupled to a classical computing device in an environment external to the dilution refrigerators, according to some embodiments.

FIG. 17A is high-level diagram illustrating an example neuro-thermodynamic computer comprising a thermodynamic chip (e.g., that implements multiple energy-based models (EBMs) and a relay gadget) included in a dilution refrigerator and coupled to a classical computing device that is also included in the dilution refrigerator, according to some embodiments.

FIG. 17B is high-level diagram illustrating an example neuro-thermodynamic computer comprising multiple thermodynamic chips (e.g., that implement respective energy-based models (EBMs) and a relay gadget) included in respective dilution refrigerators and coupled to respective classical computing devices that are also included in the respective dilution refrigerators, according to some embodiments.

FIG. 18 is high-level diagram illustrating an example neuro-thermodynamic computer comprising one or more thermodynamic chips (e.g., that implement respective energy-based models (EBMs) and a relay gadget) coupled to a classical computing device in an environment other than a dilution refrigerator, according to some embodiments.

FIG. 19 is a high-level diagram illustrating oscillators included in a substrate of a thermodynamic chip and a mapping of the oscillators to logical neurons or synapses of the thermodynamic chip, according to some embodiments.

FIG. 20 is an additional high-level diagram illustrating oscillators included in a substrate of a thermodynamic chip mapped to logical neurons, weights, and biases (e.g., synapses) of a neuro-thermodynamic computing system, according to some embodiments.

FIG. 21 is a block diagram illustrating an example computer system that may be used in at least some embodiments.

While embodiments are described herein by way of example for several embodiments and illustrative drawings, those skilled in the art will recognize that embodiments are not limited to the embodiments or drawings described. It should be understood, that the drawings and detailed description thereto are not intended to limit embodiments to the particular form disclosed, but on the contrary, the intention is to cover all modifications, equivalents and alternatives falling within the spirit and scope as defined by the appended claims. The headings used herein are for organizational purposes only and are not meant to be used to limit the scope of the description or the claims. As used throughout this application, the word “may” is used in a permissive sense (i.e., meaning having the potential to), rather than the mandatory sense (i.e., meaning must). Similarly, the words “include,” “including,” and “includes” mean including, but not limited to. When used in the claims, the term “or” is used as an inclusive or and not as an exclusive or. For example, the phrase “at least one of x, y, or z” means any one of x, y, and z, as well as any combination thereof.

### DETAILED DESCRIPTION

The present disclosure relates to methods, systems, and an apparatus for performing computer operations using a thermodynamic chip and more specifically to relaying thermodynamic information between components, such as components of a neuro-thermodynamic computing device, while maintaining the information in a thermodynamic state. This can be contrasted with other approaches to communicate information that involve reading out thermodynamic information, such as using a classical computing device, and then relaying the information in classical form. For example, the ability to relay thermodynamic information directly between components in a neuro-thermodynamic computer avoids issues associated with readout to a classical computing device, such as read-out error, loss of information, and/or delays associated with performing readout. Moreover, if the information is to be used by another component of a neuro-thermodynamic computing device, relay of the information in a thermodynamic state avoids other delays such as would be incurred if required to initialize a receiving component to have an initial state corresponding to a state of the thermodynamic information that was read out from another component, wherein the relayed information is not already in a thermodynamic state. In some embodiments, such relay techniques as described herein may be used to relay thermodynamic information between energy-based models (EBMs). Such energy-based models (EBMs) may include trained models that evolve according to Langevin dynamics, and which may be used to generate inferences, such as machine learning (ML) inferences. For example, an ML model used to generate an ML inference may be physically implemented as a trained energy-based model (EBM).

Multiple types of computations, such as inference and Gibbs sampling can be greatly accelerated when implemented on a thermodynamic processor, where the individual components of such models are oscillators implemented on superconducting circuit elements. However, in many applications, the desired operations need to be performed on circuits with multiple components (with each component performing a particular computation), which can add significant constraints on the selection of parameters for each of the oscillator of the thermodynamic chip. For example, if frequency or mass differentials (or combinations of both) between oscillators are used to cause thermodynamic information flow to move analog information between components in a desired manner, there are a limited number of easily achievable frequency and mass combinations of oscillators. Thus, the complexity of such systems quickly becomes self-limiting due to the inability to achieve thermodynamic information flow when primarily relying on mass and/or frequency differentials between oscillators to guide information flow. For example, in order to achieve thermodynamic information flow, it may be necessary that a value of mass times frequency squared of a sending oscillator is much greater than a corresponding value of mass times frequency squared of a receiving oscillator. As such, having the ability to modularize large circuits, with each modular component responsible for a particular task is needed for implementing such models using thermodynamic processors. In such a modularized approach, mass and/or frequency differentials can be used within a given model, but a relay gadget can be used to relay information between modules, without a need to consider oscillator parameters of a given module when selecting oscillator parameters of another module. This modularization greatly simplifies the selection of oscillator parameters.

As described herein, a relay gadget provides a solution to controlling thermal information flow without having to rely on varying mass and frequency combinations between components to drive the thermodynamic information flow. For example, a relay gadget includes a relay oscillator that has a controllably adjustable mass and/or frequency that can be used to couple to oscillators belonging to other modules. This allows controlled thermodynamic information flow without having to worry about relative mass and/or frequency sizing between oscillators of the components (e.g. such as oscillators of an input EBM and oscillators of a destination EBM). For example, using a relay oscillator reduces the required constraints on the selection of parameters for oscillators belonging to different modules. The relay oscillator can also be used to obtain samples from various degrees of freedom of an oscillator. Such samples can be used to do Gibbs sampling.

In some embodiments, a relay oscillator may be implemented using a fully analog scheme. In such embodiments, a second oscillator may optionally be included in a relay gadget with the relay oscillator, wherein the second oscillator acts as a bias (e.g., bias oscillator). The bias oscillator may be used to enable the relay oscillator to maintain its equilibrium value for longer time scales as the coupling between the relay oscillator and output oscillator from one of the modules is turned off. Also, in some embodiments, the relay oscillator has a time dependent mass and constant frequency, and in other embodiments the relay oscillator has a constant mass but time-dependent frequency.

In some embodiments, a neuro-thermodynamic processor may be configured such that learning algorithms for learning parameters of an energy-based model may be applied using Langevin dynamics. For example, as described herein, a thermodynamic chip of a neuro-thermodynamic processor may be configured such that, given a Hamiltonian that describes an energy-based model, weights and biases (e.g., synapses) may be calculated based on measurements taken from the thermodynamic chip as it naturally evolves according to Langevin dynamics. For example, a positive phase term, a negative phase term, and associated gradients needed to determine updated weights and biases for the energy-based model may be simply computed on an accompanying classical computing device, such as a field programmable gate array (FPGA) or application specific integrated circuit (ASIC), based on measurements taken from the oscillators of the thermodynamic chip. Such calculations performed on the accompanying classical computing device may be simple and non-complex as compared to other approaches that use the classical computing device to determine statistical probabilities (e.g., without using a thermodynamic chip). Also, in some embodiments, weights and biases used in an energy-based model may be determined iteratively, for example wherein a classical computing device is used to generate updated weights and biases, and wherein resulting inference performance is compared to training data to determine whether additional iterative learning is needed.

In some embodiments, physical elements of a thermodynamic chip may be used to physically model evolution according to Langevin dynamics. For example, in some embodiments, a thermodynamic chip includes a substrate comprising oscillators implemented using superconducting flux elements. The oscillators may be mapped to neurons (visible or hidden) that “evolve” according to Langevin dynamics. For example, the oscillators of the thermodynamic chip may be initialized in a particular configuration and allowed to thermodynamically evolve. As the oscillators “evolve” degrees of freedom of the oscillators may be sampled. Values of these sampled degrees of freedom may represent, for example, vector values for neurons or synapses that evolve according to Langevin dynamics. For example, algorithms that use stochastic gradient optimization and require sampling during training, such as those proposed by Welling and Teh, and/or other algorithms, such as natural gradient descent, mirror descent, etc. may be implemented using a thermodynamic chip. In some embodiments, a thermodynamic chip may enable such algorithms to be implemented directly by sampling the neurons and/or synapses (e.g., degrees of freedom of the oscillators of the substrate of the thermodynamic chip) without having to calculate statistics to determine probabilities. As another example, thermodynamic chips may be used to perform autocomplete tasks, such as those that use Hopfield networks, which may be implemented using the Welling and Teh algorithm. For example, visible neurons may be arranged in a fully connected graph (such as a Hopfield network, etc.), and the values of the auto complete task may be learned using the Welling and Teh algorithm. In some embodiments, a relay gadget may be used to sample visible neurons of a first energy-based model (EBM) and provide the sampled thermodynamic information as an input to another energy-based model (EBM).

In some embodiments, a thermodynamic chip includes superconducting flux elements arranged in a substrate, wherein the thermodynamic chip is configured to modify magnetic fields that couple respective ones of the oscillators with other ones of the oscillators. In some embodiments, non-linear (e.g., anharmonic) oscillators are used that have dual-well potentials. These dual-well oscillators may be mapped to neurons of a given energy-based model that the thermodynamic chip is being used to implement. Also, in some embodiments, at least some of the oscillators may be harmonic oscillators with single-well potentials. In some embodiments, oscillators may be implemented using superconducting flux elements with varying amounts of non-linearity. In some embodiments, an oscillator may have a single well potential, a dual-well potential, or a potential somewhere in a range between a single-well potential and a dual-well potential. In some embodiments, visible neurons may be mapped to oscillators having a single well potential, a dual-well potential, or a potential somewhere in a range between a single-well potential and a dual-well potential.

In some embodiments, oscillators of a thermodynamic chip may also be used to represent values of weights and biases of the energy-based model. Thus, weights and biases that describe relationships between neurons may also be represented as dynamical degrees of freedom, e.g., using oscillators of the thermodynamic chip (e.g., synapse oscillators).

In some embodiments, parameters of an energy-based model or other learning algorithm may be learned through evolution of the oscillators of a thermodynamic chip.

As mentioned above, in some embodiments, the weights and biases of an energy-based model may be dynamical degrees of freedom (e.g., oscillators of a thermodynamic chip), in addition to neurons (hidden or visible) being dynamic degrees of freedom (e.g., represented by other oscillators of the thermodynamic chip). In such configurations, gradients needed for learning algorithms can be obtained by performing sampling of the synapse oscillators, such as position samples or momentum samples. For example, measurements of the synapse oscillators (position or momentum) performed on a time scale proportional to a thermalization time of the synapse oscillators, or on shorter time scales than the thermalization times of the synapse oscillators, can be used to compute time-averaged gradients in addition to space averaged gradients. In some embodiments, the variance of the time averaged or space averaged gradient (determined using synapse oscillator measurements) scales as 1/t where t is the total measurement time. These gradients can be used to calculate new weights and bias values that may be used as synapse values in an updated version of the energy-based model. The process of making measurements and determining updated weights and biases may be repeated multiple times until a learning threshold for the energy-based model has been reached.

For example, there are various learning algorithms where one must use both positive and negative phase terms to perform parameter updates. For instance, in the implementation by Welling and Teh the parameters are updated as follows:

$${θ}_{t + 1} = {θ}_{t} + \frac{{ϵ}_{t}}{2} ( - {∇}_{{θ}_{t}} {ℰ}_{p} ( {θ}_{t} ) - N \frac{1}{n} {\sum }_{i = 1}^{n} {∇}_{{θ}_{t}} ℰ ( {θ}_{t} , {x}_{{t}_{i}} ) - {𝔼}_{x ∼ {p}_{{θ}_{t}} ( x )} [ {∇}_{{θ}_{t}} ℰ ( {θ}_{t} , x ) ] ) + {η}_{t}$$

where εₚ(θₜ) is some prior potential and the probability distribution for an energy-based model (EBM) with parameters θₜ given by pθₜ(x)=e^{-ε(θ}^{ₜ}^{,x)}/Z, where Z is a partition function. In the above equation, the first gradient term, where the visible nodes are clamped to the data will be referred to as the positive phase term. The second gradient term, where the visible nodes are sampled from x˜pθₜ(x) will be referred to as the negative phase term (e.g., where the visible nodes are unclamped). When hidden neurons are present, the parameter update rule is given by:

$${θ}_{t + 1} = {θ}_{t} + \frac{{ϵ}_{t}}{2} ( - {∇}_{{θ}_{t}} {ℰ}_{p} ( {θ}_{t} ) - N \frac{1}{n} {\sum }_{i = 1}^{n} {𝔼}_{z ∼ {p}_{{θ}_{t} ( z \vert {x}_{{t}_{i}} )}} [ {∇}_{{θ}_{t}} ℰ ( {θ}_{t} , {x}_{{t}_{i}} z ) ] - {𝔼}_{( x , z ) ∼ {p}_{{θ}_{t}} ( x , z )} [ {∇}_{{θ}_{t}} ℰ ( {θ}_{t} , x , z ) ] + {η}_{t}$$

For a neuro-thermodynamic processor, which includes visible neurons coupled via weights and biases that are also represented by degrees of freedom (e.g., synapse oscillators), the dynamics of the system for a three-body coupling between the synapse oscillators and the neuron oscillators (visible or hidden) are described by the following Hamiltonian:

$${H}_{total} = {\sum }_{j ∈ {𝒱}_{v i s}} ( \frac{{p}_{{n}_{j}}^{2}}{2 {m}_{{n}_{j}}^{( v )}} + {{E}_{L}^{( v )} ( {ϕ}_{{n}_{j}} - {\tilde{ϕ}}_{L}^{( v )} )}^{2} + {E}_{J 0}^{( v )} cos ( {\tilde{ϕ}}_{DC}^{( v )} / 2 ) ( 1 - cos ( {ϕ}_{{n}_{j}} ) ) ) + {\sum }_{k , l ∈ ℰ} ( \frac{{p}_{{s}_{j}}^{2}}{2 {m}_{{s}_{k , l}}^{( w )}} + {{E}_{L}^{( w )} ( {φ}_{{s}_{k , l}} - {\tilde{ϕ}}_{L}^{( w )} )}^{2} + {E}_{{J 0}^{}}^{( w )} cos ( {\tilde{ϕ}}_{DC}^{( w )} / 2 ) ( 1 - cos ( {ϕ}_{{s}_{k , l}} ) ) ) + {\sum }_{j ∈ {𝒱}_{v i s}} ( \frac{{p}_{{b}_{j}}^{2}}{2 {m}_{{b}_{j}}^{( b )}} + {{E}_{L}^{( b )} ( {ϕ}_{{b}_{j}} - {\tilde{ϕ}}_{L}^{( b )} )}^{2} + {E}_{J 0}^{( b )} cos ( {\tilde{ϕ}}_{DC}^{( b )} / 2 ) ( 1 - cos ( {ϕ}_{{b}_{j}} ) ) ) + ( α {\sum }_{\{ k , l \} ∈ ℰ} {ϕ}_{{s}_{k l}} {ϕ}_{{n}_{k}} {ϕ}_{{n}_{l}} + β {\sum }_{j ∈ 𝒱} {ϕ}_{{n}_{j}} {ϕ}_{{b}_{j}} )$$

Note that the above Hamiltonian uses a representation of couplings between neuron oscillators and synapse oscillators given by the terms proportional to alpha and beta. However, in some embodiments, a Hamiltonian with more general terms may be used. The above Hamiltonian is given as an example of an energy-based model, but others may be used within the scope of the present disclosure.

Broadly speaking, classes of algorithms that may benefit from implementation using a thermodynamic chip include those algorithms that involve probabilistic inference. Such probabilistic inferences (which otherwise would be performed using a CPU or GPU) may instead be delegated to the thermodynamic chip for a faster and more energy efficient implementation. At a physical level, the thermodynamic chip harnesses electron fluctuations in superconductors coupled in flux loops to model Langevin dynamics. In some embodiments, architectures such as those described herein may resemble a partial self-learning architecture, wherein classical computing device(s) (e.g., a FPGA, ASIC, etc.) may be relied upon only to perform simple tasks such as summing measured values and performing other non-compute intensive operations in order to implement a learning algorithm.

Note that in some embodiments, electro-magnetic or mechanical (or other suitable) oscillators may be used. A thermodynamic chip may implement neuro-thermodynamic computing and therefore may be said to be neuromorphic. For example, the neurons implemented using the oscillators of the thermodynamic chip may function as neurons of a neural network that has been implemented directly in hardware. Also, the thermodynamic chip is “thermodynamic” because the chip may be operated in the thermodynamic regime slightly above 0 Kelvin, wherein thermodynamic effects cannot be ignored. For example, some thermodynamic chips may be operated within the milli-Kelvin range, and/or at 2, 3, 4, etc. degrees Kelvin. The term thermodynamic chip also indicates that the thermal equilibrium dynamics of the neurons are used to perform computations. In some embodiments, temperatures less than 15 Kelvin may be used. Though other temperatures ranges are also contemplated. This also, in some contexts, may be referred to as analog stochastic computing. In some embodiments, the temperature regime and/or oscillation frequencies used to implement the thermodynamic chip may be engineered to achieve certain statistical results. For example, the temperature, friction (e.g., damping) and/or oscillation frequency as well as masses, may be controlled variables that ensure the oscillators evolve according to a given dynamical model, such as Langevin dynamics. In some embodiments, temperature may be adjusted to control a level of noise introduced into the evolution of the neurons. As yet another example, a thermodynamic chip may be used to model energy models that require a Boltzmann distribution. Also, a thermodynamic chip may be used to solve variational algorithms and perform learning tasks and operations.

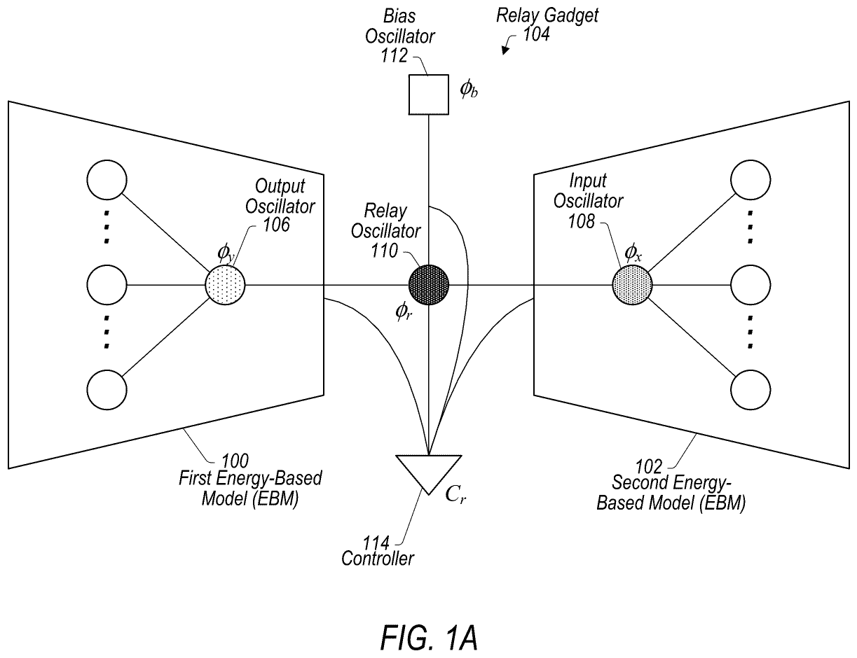

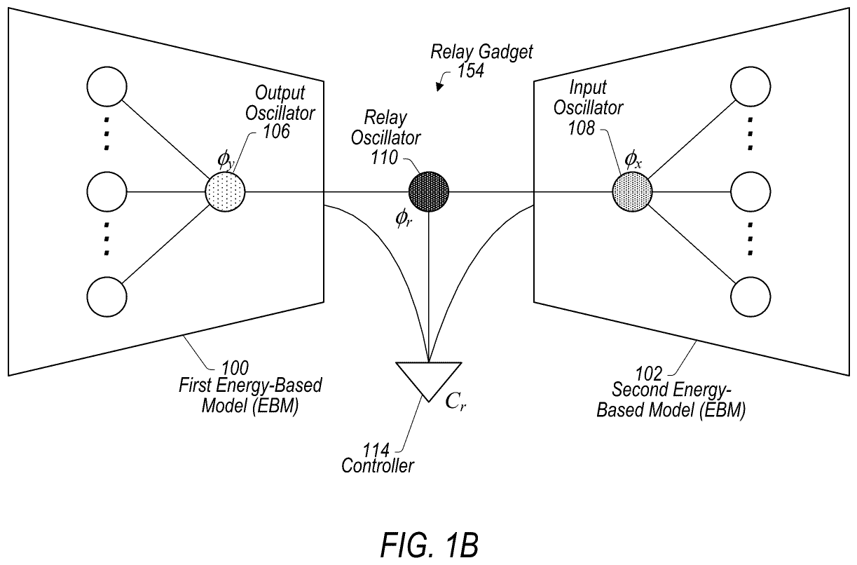

FIG. 1A is high-level diagram illustrating a first energy-based model (EBM) implemented using a thermodynamic chip, a second energy-based model (EBM) implemented using a thermodynamic chip, and a relay gadget implemented using a thermodynamic chip, wherein the relay gadget is configured to relay thermodynamic information between the first energy-based model (EBM) and the second energy-based model (EBM), according to some embodiments.

In some embodiments, a relay oscillator gadget, such as relay oscillator gadget 104, receives thermodynamic information from an input source, such as oscillator 106, and relays the thermodynamic information to an output destination, such as oscillator 108. In some embodiments, the oscillator 106 may be an output oscillator 106 of a first energy-based model (EBM) 100 and the oscillator 108 may be an input oscillator 108 of a second energy-based model (EBM) 102. In some embodiments, the thermodynamic information being relayed from the output oscillator 106 to the input oscillator 108 may be a position degree of freedom. As such, FIG. 1A shows an output position degree of freedom (ϕ_{y}) of the output oscillator 106 and an input position degree of freedom (ϕₓ) of the input oscillator 108, as well as a relay position degree of freedom (ϕᵣ) of the relay oscillator 110 and a bias position degree of freedom (ϕ_{b}) of the bias oscillator 112. Additionally, controller 114 is shown, which may be an on-chip controller. Controller 114 causes pulses to be emitted in a time dependent manner to orchestrate coupling of the relay oscillator 110 to the output oscillator 106, coupling of the relay oscillator 110 to the bias oscillator 112, adjustment of a mass or frequency of the relay oscillator 110, and a coupling of the relay oscillator 110 to the input oscillator 108. In some embodiments, the controller 114 may be pre-programmed to emit the relevant pulses and control signals in a time dependent sequence in order to execute a relay operation.

An example Hamiltonian of the coupled system shown in FIG. 1A is given by:

$${H}_{fan} = \frac{{π}_{r}^{2}}{2 {m}_{r} ( t )} + \frac{{π}_{y}^{2}}{2 {m}_{y}} + \frac{{π}_{x}^{2}}{2 {m}_{x}} + \frac{{π}_{b}^{2}}{2 {m}_{b}} + \frac{1}{2} {m}_{r} ( t ) {ω}_{r}^{2} ( t ) {ϕ}_{r}^{2} + \frac{1}{2} {m}_{b} {ω}_{b}^{2} {ϕ}_{b}^{2} + \frac{1}{2} {m}_{y} {{ω}_{y}^{2} ( {ϕ}_{y} - {y}_{e} )}^{2} + \frac{1}{2} {m}_{x} {ω}_{x}^{2} {ϕ}_{x}^{2} + {λ}_{A} ( t ) {( {ϕ}_{y} - {ϕ}_{r} )}^{2} + {λ}_{B} ( t ) {ϕ}_{b} {ϕ}_{r} + {λ}_{X} ( t ) {ϕ}_{r} {ϕ}_{X}$$

Note that the terms in the Hamiltonian including the λ_{A}, λ_{B}, and λ_{X} terms describe the coupling between the relay oscillators and the other three oscillators, e.g. the output oscillator 106, the bias oscillator 112, and the input oscillator 108. Also, note that all three coupling terms are time dependent, based on the λ_{A}, λ_{B}, and λ_{X} pulses controlled by controller 114. Additionally, note that the mass (or the frequency) of the relay oscillator 110 is time dependent, where the mass (or frequency) of the relay oscillator is also controlled by controller 114.

More particularly, the controller 114 emits pulses 14 to couple the position degree of freedom (ϕ_{y}) of the output oscillator 106 to the position degree of freedom (ϕᵣ) of the relay oscillator 110. This coupling may remain turned on for some time. Then, once the coupling between the position degree of freedom (ϕ_{y}) of the output oscillator 106 and the position degree of freedom (ϕᵣ) of the relay oscillator 110 is turned off, the controller 114 causes pulses λ_{B} to be emitted to couple the position degree of freedom (ϕᵣ) of the relay oscillator 110 to the position degree of freedom (ϕ_{b}) of the bias oscillator 112, and simultaneously emits control signals to cause the mass of the relay oscillator 110 to be increased (or alternatively emits control signals to cause the oscillation frequency of the relay oscillator 110 to be tuned, for example decreased). When coupled to the relay oscillator 110, the bias position degree of freedom (ϕ_{b}) of the bias oscillator 112 acts as a bias to the relay oscillator 110 and helps to ensure that the relay position degree of freedom (ϕᵣ) of the relay oscillator 110 maintains its equilibrium value (that it has acquired from the output oscillator 106). After the relay oscillator 110 has reached an appropriately large mass (or tuned frequency), the controller 114 causes pulses λ_{X} to be emitted to couple the position degree of freedom (ϕᵣ) of the relay oscillator 110 (having the increased mass or tuned frequency) to the position degree of freedom (ϕ_{X}) of the input oscillator 108. Also, in some embodiments, the controller 114 may cause pulses λ_{X} and pulses λ_{B} to be emitted at the same time, such that the relay oscillator 110 is coupled to the bias oscillator 112 simultaneously with being coupled to the input oscillator 108.

In some embodiments the following pulse shapes may be used for λ_{A}, λ_{B}, and λ_{X}. Though in some embodiments, other suitable pulse shapes may be used.

$${λ}_{A} ( t ) = {λ}_{A} ( σ ( {k}_{A} ( t - {t}_{1} ) ) - σ ( {k}_{A} ( t - {t}_{2} ) ) )$$

$${λ}_{B} ( t ) = - {λ}_{B} σ ( {k}_{B} ( t - {t}_{1}^{( B )} ) ) + {λ}_{0}^{( B )}$$

$${λ}_{X} ( t ) = {λ}_{X} σ ( {k}_{X} ( t - {t}_{1}^{( X )} ) ) + {λ}_{0}^{( X )}$$

where σ(t) is the sigmoid function:

$$σ ( t ) = \frac{1}{1 + {e}^{- t}} .$$

In some embodiments, λ_{A}, λ_{B}, and λ_{X}, as well as k_{A}, k_{B}, and k_{X} may be tuned to improve results. Also, t₁, t₂, t₁^{(B)}, and t₁^{(X)} may be tuned.

Without loss of generality, the position degree of freedom of the output oscillator 106 (ϕ_{y}) is considered to have an equilibrium value (yₑ) (after energy-based model 100 has evolved for some time and reached a thermal equilibrium). Also, the position degree of freedom (ϕ_{y}) of the output oscillator 106 is considered to have a potential given by

$$\frac{1}{2} {m}_{y} {{ω}_{y}^{2} ( {ϕ}_{y} - {y}_{e} )}^{2} .$$

It should be noted in practice that the output oscillator 106 may be coupled to various other oscillators of the first energy-based model 100 (as shown in FIG. 1A) which would cause it to have the yₑ equilibrium value. Thus, to be more comprehensive,

$$\frac{1}{2} {m}_{y} {{ω}_{y}^{2} ( {ϕ}_{y} - {y}_{e} )}^{2}$$

may be replaced by a potential term that takes into account these couplings, such as

$$\frac{1}{2} {m}_{y} {{ω}_{y}^{2} ( {ϕ}_{y} - {y}_{e} )}^{2} + {\sum }_{j} {λ}_{Y}^{( j )} {φ}_{y} {φ}_{j} or \frac{1}{2} {m}_{y} {{ω}_{y}^{2} ( {φ}_{y} - {y}_{e} )}^{2} + {λ}_{Y} {\sum }_{j} {{λ}_{Y}^{( j )} ( {φ}_{y} - {φ}_{j} )}^{2} ,$$

where the ϕⱼ degrees of freedom are degrees of freedom of other oscillators in the first energy-based model 100 that are coupled to the position degree of freedom (ϕ_{y}) of the output oscillator 106. However, this difference (or said another way, simplification) manifests itself in a slightly different value for the equilibrium value (yₑ), or depending on the couplings, may result in the same yₑ equilibrium value. But this simplification does not affect the equilibrium results of the relay oscillator 110. A similar issue applies to the input oscillator 108, which is also coupled to other oscillators of the second energy-based model 102. Also, in some embodiments, multiple relay oscillators 110 may be coupled to multiple input oscillators (e.g. additional input oscillators in addition to input oscillator 108). Note that the relay oscillator 110 and the relay gadget 104 impart the equilibrium value of the output oscillator to the input oscillator, such that the position degree of freedom (ϕₓ) of the input oscillator 108 inherits the same equilibrium value as the position degree of freedom (ϕ_{y}) of the output oscillator 106, e.g. the position it had when first coupled to the relay oscillator 110 of the relay gadget 104. As such, thermodynamic information is relayed from the output oscillator 106 to the input oscillator 108 while remaining in a thermodynamic state. For example, analog information is passed between the first energy-based model 100 and the second energy-based model 102 without requiring a measurement by a classical computing device. Further note, this is done in an analog way (as opposed to a digitization that would take place during readout and re-initialization).

For a system undergoing Langevin dynamics, the equation of motion of a given oscillator (k) is given by:

$$\frac{d {φ}_{k} ( t )}{d t} = \frac{\partial {H}_{fan}}{\partial {π}_{k}}$$

$$\frac{{π}_{k} ( t )}{d t} = - γ {π}_{k} ( t ) - \frac{\partial {H}_{f a n}}{\partial {φ}_{k}} {\vert}_{t} + \sqrt{2 {m}_{k} γ {k}_{B} T} \frac{d {W}_{t}}{d t}$$

where φ denotes the position degree of freedom of the oscillator and π denotes the momentum degree of freedom of the oscillator. Using the Hamiltonian for the coupled system shown in FIG. 1A (which is given further above) and the equations of motion for position and momentum given directly above, the equations of motions for the relay oscillator 110, output oscillator 106, the bias oscillator 112, and the input oscillator 108, are respectively given by:

### Equation of Motion for the Relay Oscillator:

$${m}_{r} ( t ) \frac{{d}^{2} {ϕ}_{r}}{d {t}^{2}} + \frac{d {m}_{r} ( t )}{dt} \frac{d {ϕ}_{r}}{dt} + γ {m}_{r} ( t ) \frac{d {ϕ}_{r}}{d t} = \text{} - ( - 2 {λ}_{A} ( t ) ( {ϕ}_{y} - {ϕ}_{r} ) + {λ}_{B} ( t ) {ϕ}_{b} + {λ}_{X} ( t ) {ϕ}_{x} + {m}_{r} ( t ) {ω}_{r}^{2} {ϕ}_{r} ) + \sqrt{2 {m}_{r} ( t ) {k}_{B} T} \frac{d {W}_{t}^{( r )}}{d t}$$

$$Or$$

$${m}_{r} ( t ) \frac{{d}^{2} {φ}_{r}}{d {t}^{2}} + \frac{d {m}_{r} ( t )}{dt} \frac{d {φ}_{r}}{dt} + γ {m}_{r} ( t ) \frac{d {φ}_{r}}{d t} = \text{} - ( - 2 {λ}_{A} ( t ) ( {φ}_{y} - {φ}_{r} ) + 2 {λ}_{B} ( t ) ( {φ}_{b} + {φ}_{r} ) + 2 {λ}_{X} ( t ) ( {φ}_{r} - {φ}_{x} ) + {m}_{r} ( t ) {ω}_{r}^{2} {φ}_{r} ) + \sqrt{2 {m}_{r} ( t ) {k}_{B} T} \frac{d {W}_{t}^{( r )}}{d t}$$

Depending on whether there is a linear or quadratic coupling.

### Equation of Motion for the Output Oscillator:

$${m}_{y} \frac{{d}^{2} {φ}_{y}}{d {t}^{2}} + γ {m}_{y} \frac{d {φ}_{y}}{d t} = - ( {λ}_{A} ( t ) {φ}_{y} + {m}_{y} {ω}_{y}^{2} ( {φ}_{y} - {φ}_{c} ) ) + \sqrt{2 {m}_{y} {k}_{B} T} \frac{d {W}_{t}^{( y )}}{d t}$$

$$Or$$

$${m}_{y} \frac{{d}^{2} {φ}_{y}}{d {t}^{2}} + γ {m}_{y} \frac{d {φ}_{y}}{d t} = \text{} - ( 2 {λ}_{A} ( t ) ( {φ}_{y} - {φ}_{r} ) + {m}_{y} {ω}_{y}^{2} ( {φ}_{y} - {φ}_{c} ) ) + \sqrt{2 {m}_{y} {k}_{B} T} \frac{d {W}_{t}^{( y )}}{d t}$$

Depending on whether there is a linear or quadratic coupling.

### Equation of Motion for the Bias Oscillator:

$${m}_{b} \frac{{d}^{2} {φ}_{b}}{d {t}^{2}} + γ {m}_{b} \frac{d {φ}_{b}}{d t} = - ( {λ}_{B} ( t ) {φ}_{r} + {m}_{b} {ω}_{b}^{2} {φ}_{b} ) + \sqrt{2 {m}_{b} {k}_{B} T} \frac{d {W}_{t}^{( b )}}{d t}$$

$$Or$$

$${m}_{b} \frac{{d}^{2} {φ}_{b}}{d {t}^{2}} + γ {m}_{b} \frac{d {φ}_{b}}{d t} = - ( - 2 {λ}_{B} ( t ) ( {φ}_{r} - {ϕ}_{b} ) + {m}_{b} {ω}_{b}^{2} {φ}_{b} ) + \sqrt{2 {m}_{b} {k}_{B} T} \frac{d {W}_{t}^{( b )}}{d t}$$

Depending on whether there is a linear or quadratic coupling.

### Equation of Motion for the Input Oscillator:

$${m}_{x} \frac{{d}^{2} {φ}_{x}}{d {t}^{2}} + γ {m}_{x} \frac{d {φ}_{x}}{d t} = - ( {λ}_{X} ( t ) {φ}_{r} + {m}_{x} {ω}_{x}^{2} {φ}_{x} ) + \sqrt{2 {m}_{x} {k}_{B} T} \frac{d {W}_{t}^{( x )}}{d t}$$

$$Or$$

$${m}_{x} \frac{{d}^{2} {φ}_{x}}{d {t}^{2}} + γ {m}_{x} \frac{d {φ}_{x}}{d t} = - ( - 2 {λ}_{X} ( t ) ( {φ}_{r} - {φ}_{x} ) + {m}_{x} {ω}_{x}^{2} {φ}_{x} ) + \sqrt{2 {m}_{x} {k}_{B} T} \frac{d {W}_{t}^{( x )}}{d t}$$

Depending on whether there is a linear or quadratic coupling.

Also, the time dependent mass of the relay oscillator 110 is given by:

$${m}_{r} ( t ) = {m}_{f}^{( r )} σ ( {k}_{r} ( t - {t}_{r} ) ) + {m}_{r} .$$

FIG. 1B is high-level diagram similar to FIG. 1A, wherein the relay gadget does not include a bias oscillator, according to some embodiments.

In some embodiments, such as when the relay oscillator is configured to have a controllable time-dependent mass, the use of a bias oscillator may be omitted. For example, if the product of mass times frequency squared of a first oscillator is much larger than the product of mass times frequency of a second oscillator (that is coupled to the first oscillator) the position degree of freedom of the first oscillator (having the larger value for the product of mass times frequency squared) may be treated as a constant. Thus, for embodiments, wherein the mass of the relay oscillator can be increased such that the product of mass times frequency squared of the relay oscillator is sufficiently large, it may not be necessary to further use a bias oscillator.

More particularly, consider two oscillators (oscillator a and oscillator b) with position degrees of freedom ϕₐ and ϕ_{b}. Suppose that ϕ_{b} has equilibrium value b_{c}. Assume ϕ_{b} is a constant and consider the Hamiltonian:

$${H}_{1} = \frac{1}{2} {m}_{a} {ω}_{a}^{2} {ϕ}_{a}^{2} + λ {ϕ}_{a} {b}_{c}$$

In this case, the expectation value of φₐ at thermal equilibrium is given by:

$$〈 {ϕ}_{a} 〉 = \frac{\int a {e}^{- β {H}_{1}} da}{\int {e}^{- β {H}_{1}} da} = \frac{λ {b}_{c}}{{m}_{a} {ω}_{a}^{2}}$$

$$Choosing λ = - {m}_{a} {ω}_{a}^{2} , it gives 〈 {ϕ}_{a} 〉 = {b}_{c} .$$

Also, considering the dynamics of ϕ_{b}. The Hamiltonian is:

$${H}_{2} = \frac{1}{2} {m}_{a} {ω}_{a}^{2} {ϕ}_{a}^{2} + \frac{1}{2} {m}_{b} {{ω}_{b}^{2} ( {ϕ}_{b} - {b}_{c} )}^{2} + λ {ϕ}_{a} {ϕ}_{b}$$

Moreover, using H₂, [symbol] φₐ [symbol] is given by:

$$〈 {φ}_{a} 〉 = \frac{\int a {e}^{- β {H}_{2}} da db}{\int {e}^{- β {H}_{2}} da db} = \frac{- λ {b}_{c}}{{m}_{a} {ω}_{a}^{2} - \frac{{λ}^{2}}{{m}_{b} {ω}_{b}^{2}}} = \frac{{b}_{c}}{1 - \frac{{m}_{a} {ω}_{a}^{2}}{{m}_{b} {ω}_{b}^{2}}}$$

where λ is set such that λ=−mₐωₐ². Note that if mₐωₐ². <<m_{b}ω_{b}², then [symbol] φₐ [symbol] ≈b_{c}. As such as long as the mass times frequency squared of the oscillator a having position degree of freedom φₐ is much less than the mass times frequency squared of the oscillator b having position degree of freedom φ_{b}, the position degree of freedom φ_{b} can be treated as a constant, with the constant being the thermal equilibrium value of φ_{b}.

Said another way, if the product of mass times frequency squared of the relay oscillator 110 is increased to be sufficiently large, then the inherited equilibrium value acquired from the output oscillator 106 can be treated as a constant, while held by the relay oscillator 110. Also, as long as the product of mass times frequency squared of the relay oscillator 110 is sufficiently large as compared to the corresponding value of mass times frequency squared of the input oscillator 108, the position degree of freedom of the relay oscillator may be treated as a constant, such that it relays the held equilibrium value acquired from the output oscillator 106 of the first EBM 100 to the input oscillator 108 of the second EBM 102.

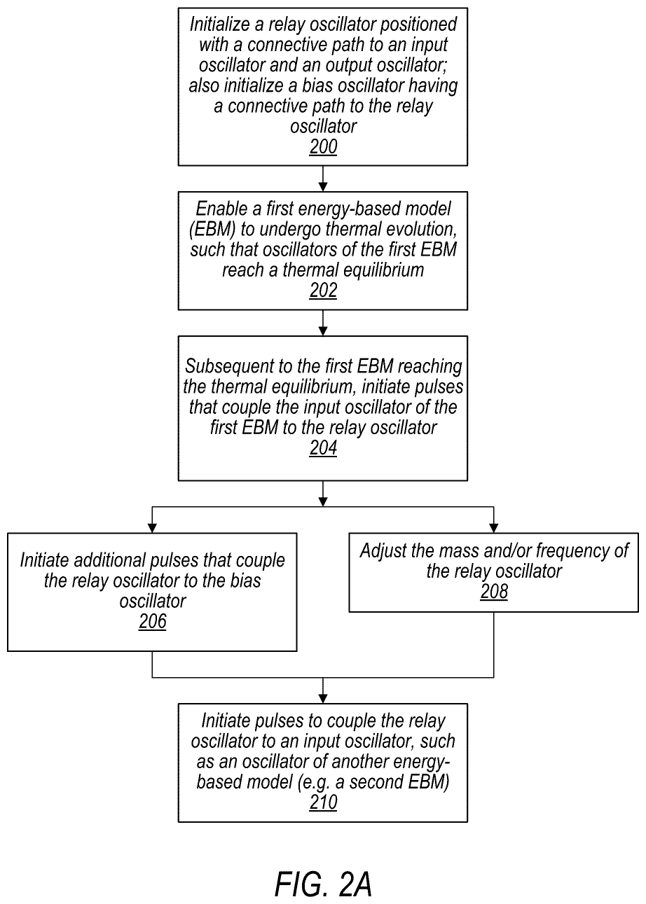

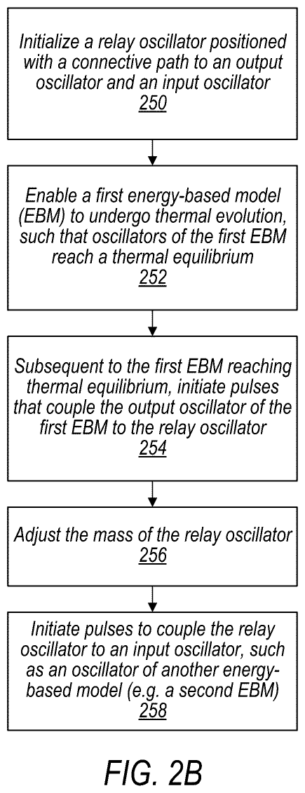

FIG. 2A is a high-level flowchart illustrating a process of relaying thermodynamic information between an output oscillator, such as of a first energy-based model (EBM), and an input oscillator, such as of a second energy-based model (EBM), according to some embodiments.

At block 200 a relay oscillator is initialized, wherein the relay oscillator is positioned such that it has connectivity to an output oscillator, such as output oscillator 106 of energy-based model 100, and has connectivity to an input oscillator, such as input oscillator 108 of energy-based model 102. Additionally, a bias oscillator is initialized, wherein the bias oscillator has connectivity to the relay oscillator. For example, bias oscillator 112 may be initialized and is positioned in a way that it can be coupled to relay oscillator 110.

At block 202, the first energy-based model comprising the output oscillator, such as energy-based model 100 that includes output oscillator 106, is enabled to undergo thermal evolution such that the energy-based model evolves according to Langevin dynamics. The evolution may be enabled to occur for an amount of time such that the first energy-based model reaches a thermal equilibrium. As an example, the first energy-based model may represent a trained model that is configured to perform inference, and at least some oscillators of the first energy-based model may be clamped to input data, wherein inference results are represented by other oscillators of the first energy-based model subsequent to the thermal evolution. For example, output oscillator 106 may represent the results of a computation performed by the energy-based model 100 that are to be relayed as input data to the second energy-based model 102.

At block 204, once the oscillators of the first energy-based model (e.g. energy-based model 100) have reached thermal equilibrium, the controller 114 initiates pulses (e.g. λ_{A}(t) pulses) to cause the output oscillator 106 to be coupled to the relay oscillator (e.g. relay oscillator 110).

At block 206, the controller 114 initiates additional pulses (e.g. λ_{B}(t) pulses) that cause the relay oscillator to be coupled to the bias oscillator. Recall that initially the relay oscillator 110 may have a small mass and/or frequency combination, e.g. small relative to the product of mass times frequency squared of the output oscillator 106. Because the relay oscillator has a small product of mass times frequency squared, the relay oscillator more readily takes on the position of the output oscillator (for example, as opposed to the relay oscillator pulling the output oscillator to take on the relay oscillator's position). However, due to the relatively small mass times frequency squared of the relay oscillator, if left alone the relay oscillator would quickly lose the recently inherited position, inherited from the output oscillator. To avoid this, the relay oscillator is coupled to the bias oscillator 112 at or near the same time as the relay oscillator is un-coupled from the output oscillator 106. The relay oscillator may also be coupled to the bias oscillator at or near the same time it is coupled to the input oscillator 108. Coupling the relay oscillator to the bias oscillator helps the relay oscillator to maintain the acquired thermal information (e.g. position degree of freedom, or, in some embodiments, momentum degree of freedom) the relay oscillator has acquired from the output oscillator. Also, while coupled to the bias oscillator and prior to being coupled to the input oscillator of the next EBM, a mass and/or frequency of the relay oscillator is adjusted.

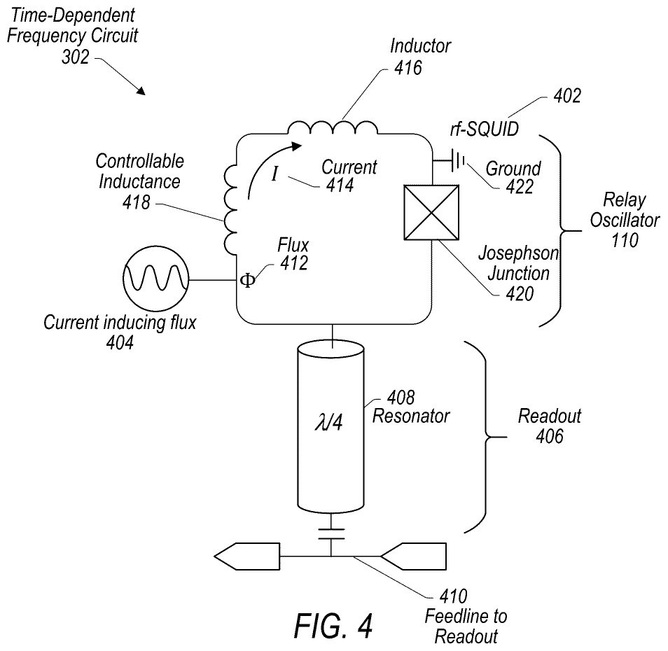

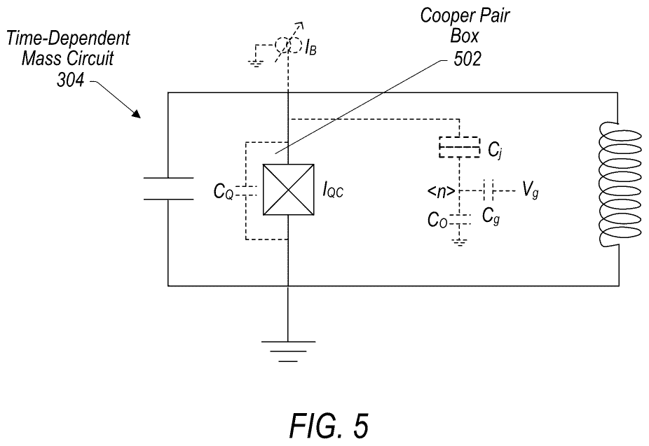

For example, at block 208, the controller 114 causes control signals to be emitted that cause the mass (or frequency) of the relay oscillator to be adjusted. The mass of the relay oscillator may be proportional to capacitance of a circuit used to implement the relay oscillator, and as described in more detail in FIG. 5, a Cooper-pair box arrangement may be used to implement a time dependent capacitance in the circuit (e.g. where the capacitance corresponds to mass). In such embodiments, the controller 114 is configured to emit control signals to cause the Cooper-pair box to increase the capacitance of the relay oscillator circuit. However, in other embodiments, mass may be kept constant, but instead frequency of the relay oscillator may be adjustable as a result of a time-dependent flux element of a circuit used to implement the relay oscillator. For example, a current inducing flux element may be added to the relay oscillator circuit as further shown in FIG. 4. In such embodiments, controller 114 may emit control signals that cause the flux of the relay oscillator to be tuned (where flux corresponds to frequency). In some embodiments blocks 206 and 208 are performed concurrently.

At block 210, the controller 114 initiates another set of one or more pulses (e.g., λ_{X}(t) pulses) to couple the relay oscillator to the input oscillator, such as input oscillator 108. The bias oscillator 112 may remain coupled to the relay oscillator 110 when the relay oscillator 110 is coupled to the input oscillator 108. Note that since the relay oscillator has had its mass (and/or frequency) adjusted prior to the coupling to the input oscillator, and since the relay oscillator remains coupled to the bias oscillator, the relay oscillator has a large value of the product of mass times frequency squared relative to the input oscillator and therefore causes the input oscillator to take on the position of the relay oscillator, which corresponds to the position of the output oscillator. In this way, the relay gadget 104 relays analog oscillator degree of freedom information (e.g. thermodynamic information) from the output oscillator to the input oscillator, without having to convert the thermodynamic information into classical form.

In some embodiments, a relay gadget, such as relay gadget 104, may perform steps similar to those described in FIG. 2A in order to relay position degree of freedom thermodynamic information, momentum degree of freedom thermodynamic information, and/or force/acceleration degree of freedom thermodynamic information.

In some embodiments, a relay gadget, such as relay gadget 104 may be used to store thermodynamic information, for example in the relay oscillator 110. Also, in some embodiments, multiple relay gadgets may be used to form a thermodynamic network between thermodynamic components. Also, in some embodiments, a relay gadget may be used to perform conditional sampling, such as Gibbs sampling

FIG. 2B is a high-level flowchart illustrating a process similar to FIG. 2A, wherein the process of relaying the thermodynamic information does not require the use of a bias oscillator, according to some embodiments.

At block 250 a relay oscillator is initialized, wherein the relay oscillator is positioned such that it has connectivity to an output oscillator, such as output oscillator 106 of energy-based model 100, and has connectivity to an input oscillator, such as input oscillator 108 of energy-based model 102. However, in contrast to the process described in FIG. 2A, in some embodiments it may not be necessary to use a bias oscillator. For example, a bias oscillator may not be needed when the relay oscillator is implemented with a time dependent mass that can be increased sufficiently to tune a value of mass times frequency squared to values that enable thermal information flow from the output oscillator to the relay oscillator, and from the relay oscillator to the input oscillator.

At block 252, the first energy-based model comprising the output oscillator, such as energy-based model 100 that includes output oscillator 106, is enabled to undergo thermal evolution such that the energy-based model evolves according to Langevin dynamics. The evolution may be enabled to occur for an amount of time such that the first energy-based model reaches a thermal equilibrium.

At block 254, once the oscillators of the first energy-based model (e.g. energy-based model 100) have reached thermal equilibrium, the controller 114 initiates pulses (e.g. 14 (t) pulses) to cause the output oscillator 106 to be coupled to the relay oscillator (e.g. relay oscillator 110).

At block 256, the controller 114 causes control signals to be emitted that cause the mass of the relay oscillator to be increased. The mass of the relay oscillator may be proportional to capacitance of a circuit used to implement the relay oscillator, and as described in more detail in FIG. 5, a Cooper-pair box arrangement may be used to implement a time dependent capacitance in the circuit (e.g. where the capacitance corresponds to mass). In such embodiments, the controller 114 is configured to emit control signals to cause the Cooper-pair box to increase the capacitance of the relay oscillator circuit.

At block 258, the controller 114 initiates another set of one or more pulses (e.g., λ_{X}(t) pulses) to couple the relay oscillator to the input oscillator, such as input oscillator 108. Note that since the relay oscillator has had its mass increased prior to the coupling to the input oscillator, the relay oscillator has a large value of the product of mass times frequency squared relative to the input oscillator and therefore causes the input oscillator to take on the position of the relay oscillator, which corresponds to the position of the output oscillator. In this way, the relay gadget 104 relays analog oscillator degree of freedom information (e.g. thermodynamic information) from the output oscillator to the input oscillator, without having to convert the thermodynamic information into classical form.

In some embodiments, a relay gadget, such as relay gadget 104, may perform steps similar to those described in FIG. 2B in order to relay position degree of freedom thermodynamic information, momentum degree of freedom thermodynamic information, and/or force/acceleration degree of freedom thermodynamic information.

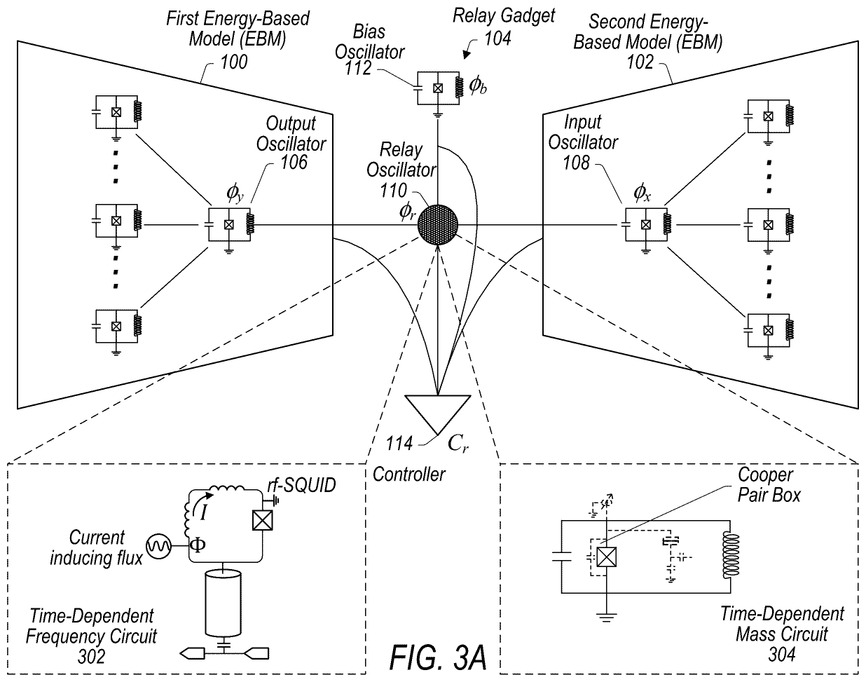

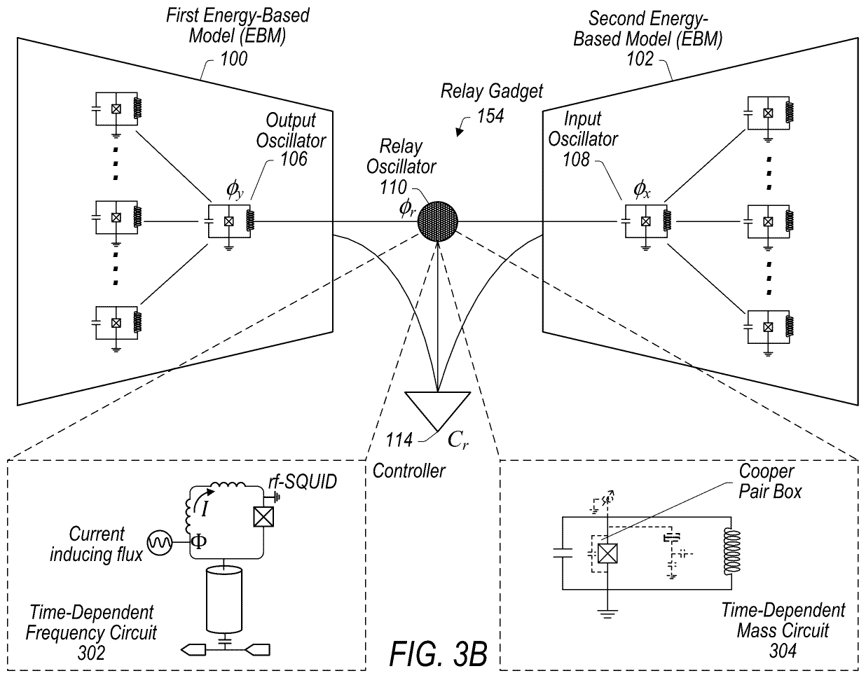

FIG. 3A is a diagram illustrating hardware components that may be used to implement oscillators of the first and second energy-based models (EBMs), as well as two different example hardware configurations of a relay oscillator that have a time-dependent mass or a time-dependent frequency, respectively, according to some embodiments.

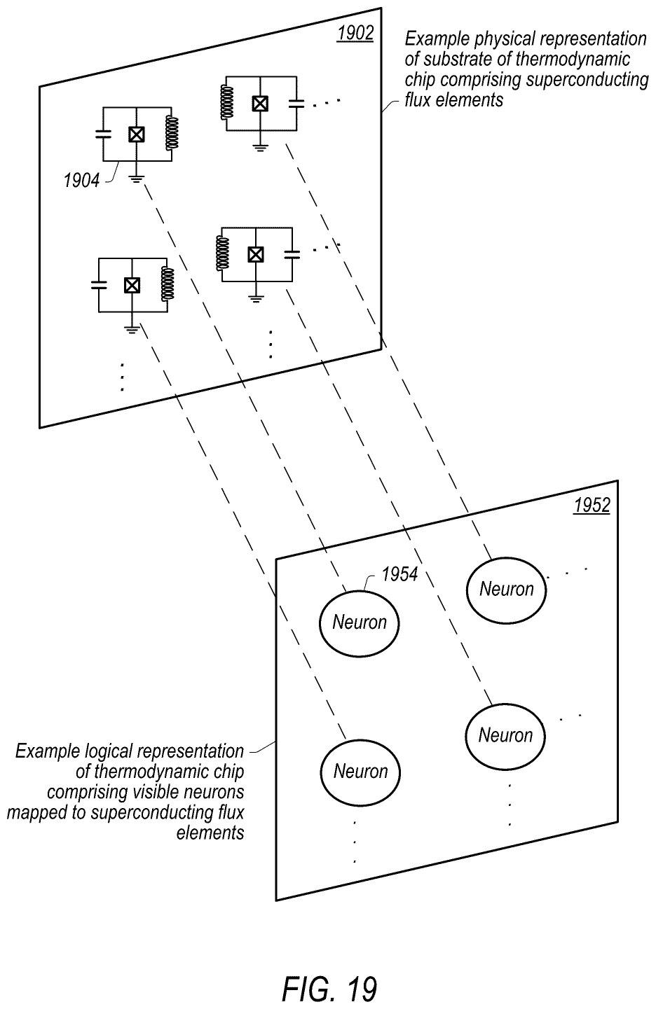

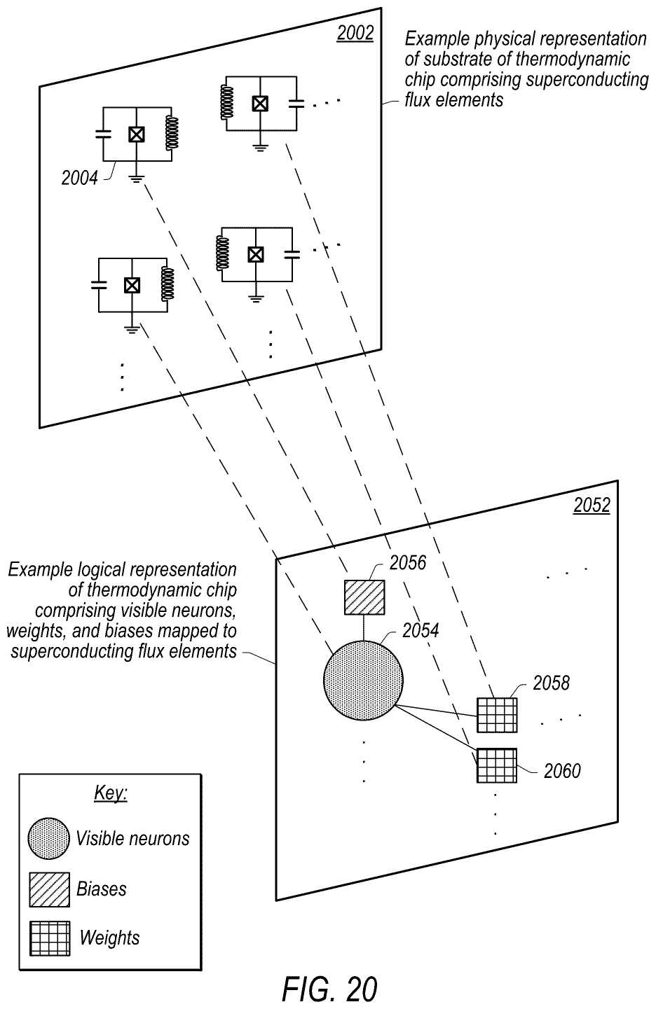

In some embodiments, each of the oscillators of the first energy-based model 100 and the second energy-based model 102, may be implemented using superconducting circuit elements, such as shown in FIG. 3A. These superconducting circuit elements may be used to implement oscillators that are mapped to visible or hidden neurons of the first or second energy-based model. Also, such oscillators may be mapped to synapses (e.g. weights or biases) of the first or second energy-based model. FIGS. 19-20 provide additional details regarding the mappings and hardware configurations used to implement example energy-based models. Also, as shown in FIG. 3A superconducting circuit elements may be used to implement the bias oscillator 112.

However, slightly different superconducting circuits may be used to implement the relay oscillator. For example, circuit 302 shows an example implementation circuit for the relay oscillator 110, wherein the circuit 302 implements a time-dependent frequency that can be controlled by controller 114. As another alternative, circuit 304 shows an example implementation circuit for the relay oscillator 110, wherein the circuit 304 implements a time-dependent mass that can be controlled by controller 114.

FIG. 3B is a diagram illustrating hardware components similar to FIG. 3A, wherein the relay gadget does not include a bias oscillator, according to some embodiments.

FIG. 4 is a diagram providing additional details regarding a hardware configuration used to implement a relay oscillator with a time-dependent frequency, according to some embodiments.

In some embodiments, a superconducting quantum interference device (SQUID) can be used in a circuit used to implement a relay oscillator with time-dependent frequency along with a controllable current line that induces a flux in the circuit. For example, time-dependent frequency circuit 302 includes rf-SQUID 402 and current line 404 that induces flux 412. Note the added flux 412 causes adjustments to the circuit flux 418 and current 414. The rf-SQUID 402 and current inducing flux 404 can be treated as a flux-tunable inductor, wherein changing the inductance of a LC-resonator changes the frequency of the time-dependent frequency circuit 302. In order to make the frequency time-dependent, a time dependent flux bias may be applied to a SQUID terminated resonator, such as shown in FIG. 4. In some embodiments, time-dependent frequency circuit 402 also includes Josephson junction 420 which is grounded 422. In some embodiments, the Josephson junction 420 and inductor 416 (along with controllable inductor 418) may form a part of relay oscillator 110. Note that in some embodiments relay oscillator 110 further includes a capacitor in parallel with the inductance and Josephson junction. However, for simplification purposes, the capacitor is not shown in FIG. 4.

In some embodiments, a value of the relay oscillator 110 may be read via readout 406. For example, a position degree of freedom of the relay oscillator 110 may be readout via readout 406. In some embodiments, readout 406 includes a resonator 408 which may have a length corresponding to ¼ the wavelength of the signal being readout from the relay oscillator 110. Also, readout 406 may include feedline 410.

Note that inducing the flux in the time-dependent frequency circuit 302 via the current line 404 and resulting induced flux 412 allows for the Josephson inductance 418 to be tuned. This inductance is in series with the resonator inductance 416 so it simply adds to the L term of the LC oscillator. In the time-dependent frequency circuit 302 shown in FIG. 4 there is a voltage antinode at the capacitor below the resonator 406 and a voltage node as the SQUID end, which is grounded.

In some embodiments, the following function may be used for the time-dependent frequency:

$${ω}_{r} ( t ) = {ω}_{f}^{( r )} σ ( {k}_{r} ( t - {t}_{r} ) ) + {ω}_{r}$$

When a time-dependent frequency is used, the equation of motion for the average position of the relay oscillator 110 becomes:

$${m}_{r} \frac{{d}^{2} {ϕ}_{r}}{d {t}^{2}} + γ {m}_{r} \frac{d {ϕ}_{r}}{d t} = - ( - 2 {λ}_{A} ( t ) ( {ϕ}_{y} - {ϕ}_{r} ) + {λ}_{B} ( t ) {ϕ}_{b} + {λ}_{X} ( t ) {ϕ}_{x} + {m}_{r} {ω}_{r}^{2} ( t ) {ϕ}_{r} ) + \sqrt{2 {m}_{r} ( t ) {k}_{B} T} \frac{{dW}_{t}^{( r )}}{d t}$$

$$Or$$

$${m}_{r} \frac{{d}^{2} {ϕ}_{r}}{d {t}^{2}} + γ {m}_{r} \frac{d {ϕ}_{r}}{d t} = - ( - 2 {λ}_{A} ( t ) ( {ϕ}_{y} - {ϕ}_{r} ) - 2 {λ}_{B} ( t ) ( {ϕ}_{r} - {ϕ}_{b} ) + 2 {λ}_{X} ( t ) ( {ϕ}_{x} - {ϕ}_{r} ) + {m}_{r} {ω}_{r}^{2} ( t ) {ϕ}_{r} ) + \sqrt{2 {m}_{r} ( t ) {k}_{B} T} \frac{{dW}_{y}^{( r )}}{d t}$$

Note that since frequency is a function of capacitance and inductance, e.g.

$$( ω = \frac{1}{\sqrt{LC}} ) ,$$

by adjusting the inductance (L), the frequency of the circuit can be controlled. For example, as discussed above, a SQUID can be treated as a flux-tunable inductor, and by changing the inductance of the flux-tunable inductor, the inductance of an LC resonator can be changed, which also changes the LC resonator's frequency. For example, a time dependent flux bias can be applied to a SQUID terminated resonator.

FIG. 5 is a diagram providing additional details regarding a hardware configuration used to implement a relay oscillator with a time-dependent mass, according to some embodiments.

A mass of an oscillator, is given by m=ϕ₀²C, where C is the capacitance of the circuit used to implement the oscillator and ϕ₀=h/2e is the reduced magnetic flux of the circuit used to implement the oscillator, e.g. a constant. Also, e is the elementary charge and h is Planck's constant. In some embodiments, a Cooper-pair box, such as Cooper-pair box 502, may be used to change the capacitance of the circuit. This allows the oscillator mass to change as a function of time, in response to control signals from controller 114. The gate voltage modulates the charge transfer through the small junction in the Cooper-pair box, thus leading to a gate-dependent capacitance.

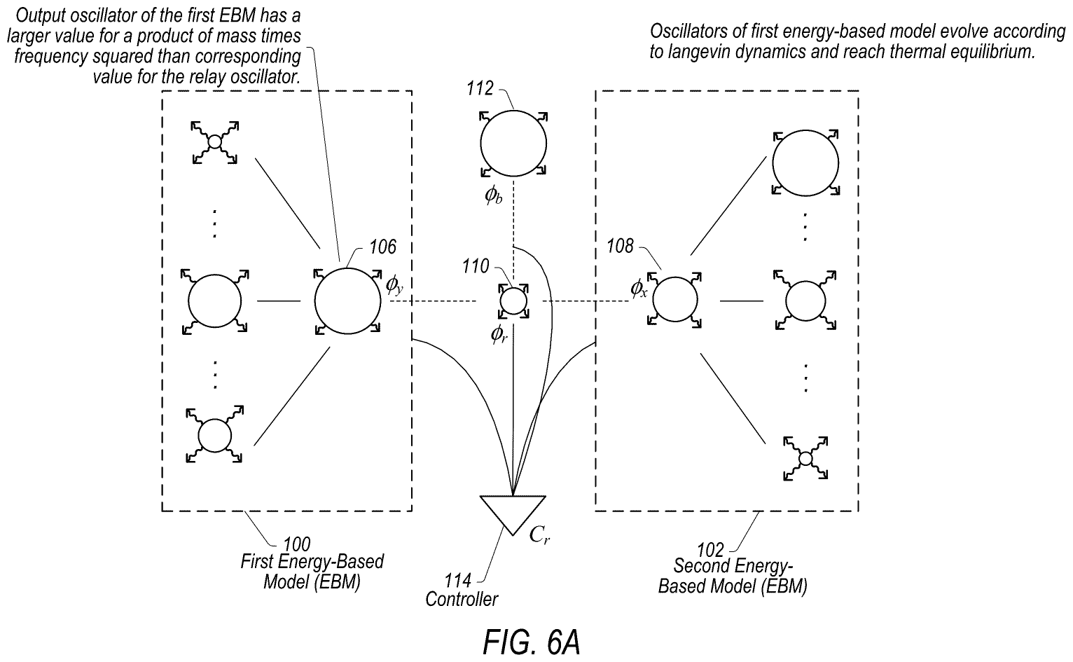

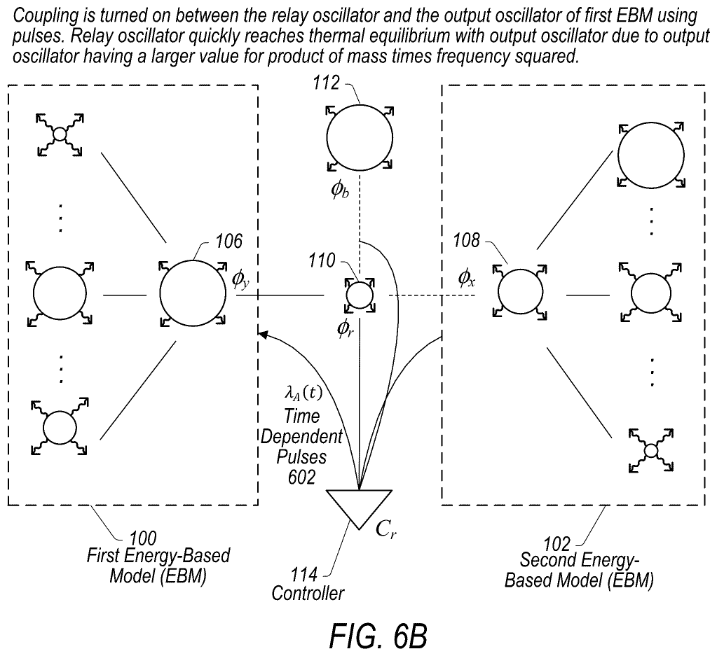

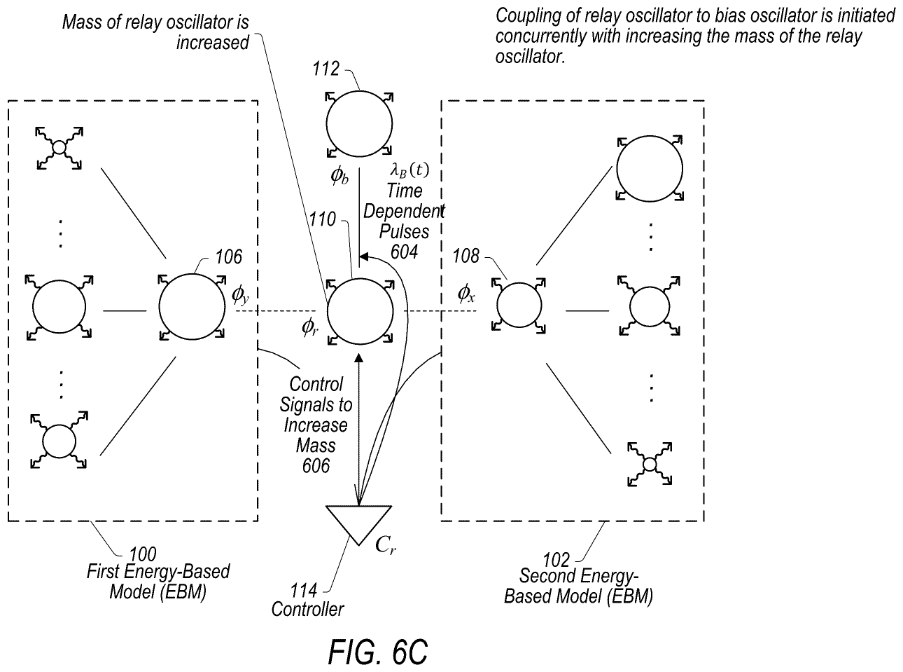

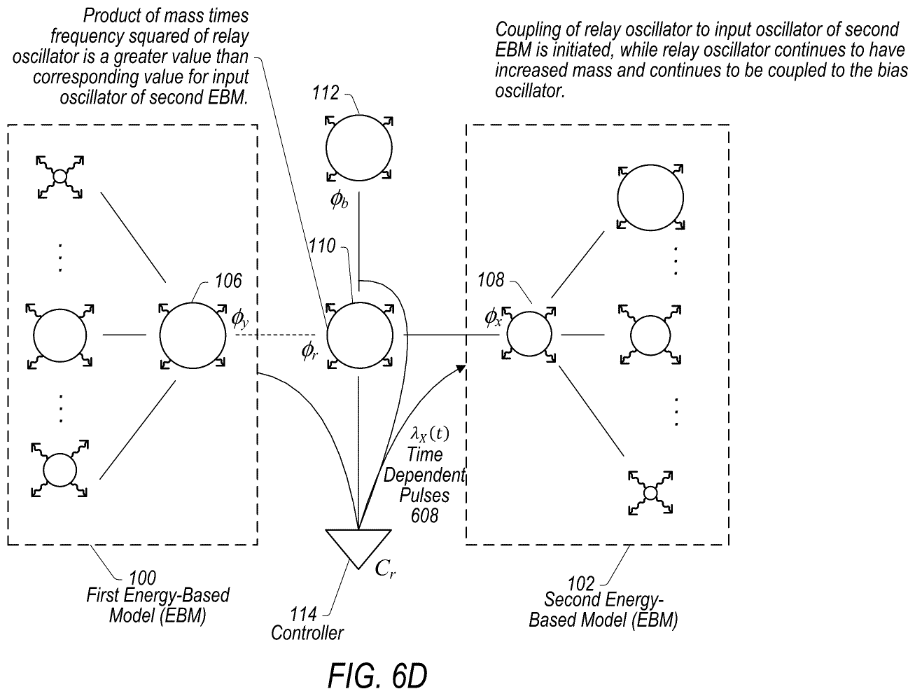

FIG. 6A is a conceptual diagram illustrating relative masses and frequencies of oscillators of the first energy-based model (EBM), relative masses and frequencies of oscillators of the second energy-based model (EBM), and relative masses and frequencies of oscillators of the relay gadget, at an initial stage of a relay process, prior to coupling the relay oscillator to the output oscillator of the first energy-based model (EBM), according to some embodiments.

As discussed above, initially the relay oscillator 110 may have a smaller value for a product of mass times frequency squared as compared to a corresponding value of mass times frequency squared of the output oscillator 106. In FIG. 6A the size of the respective circles illustrating the oscillators are used to show relative masses of the oscillators. Also, the arrows coming out from the circles are used to illustrate the motion (e.g. frequency) of the oscillators.

FIG. 6B is a conceptual diagram illustrating relative masses and frequencies of oscillators of the first energy-based model (EBM), relative masses and frequencies of oscillators of the second energy-based model (EBM), and relative masses and frequencies of oscillators of the relay gadget, at a subsequent stage of a relay process, wherein coupling is activated between the relay oscillator and the output oscillator of the first energy-based model (EBM), according to some embodiments.

Controller 114 causes time dependent pulses 602 to be emitted, which cause output oscillator 106 to be coupled to relay oscillator 110.

FIG. 6C is a conceptual diagram illustrating relative masses and frequencies of oscillators of the first energy-based model (EBM), relative masses and frequencies of oscillators of the second energy-based model (EBM), and relative masses and frequencies of oscillators of the relay gadget, at another stage of a relay process, wherein coupling is activated between the relay oscillator and the bias oscillator, and wherein the mass of the relay oscillator is increased, according to some embodiments.

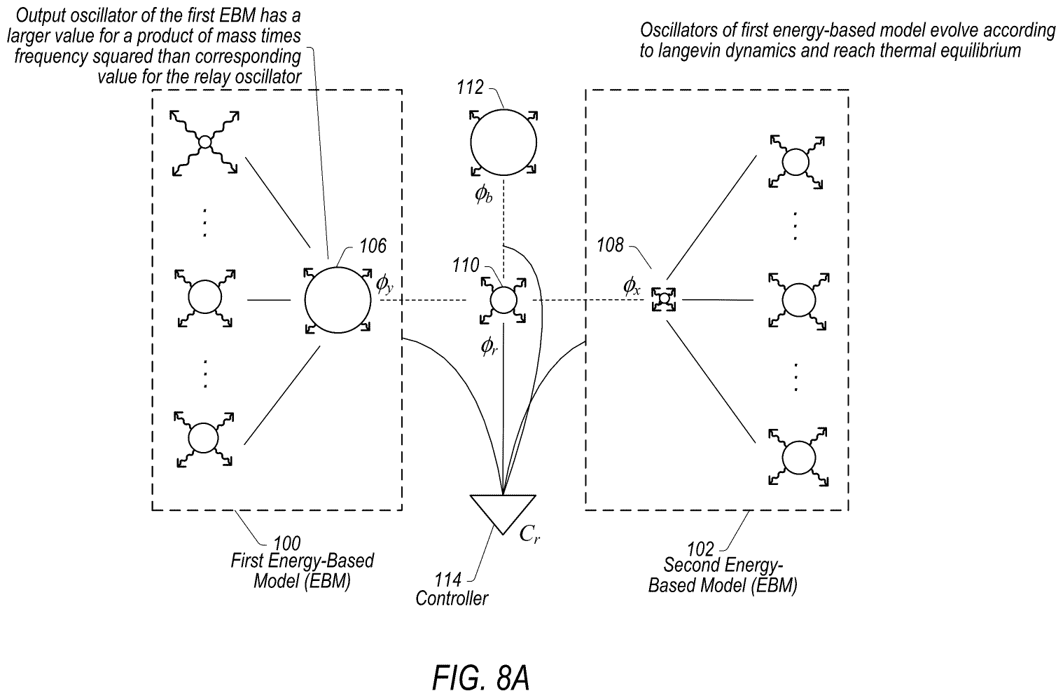

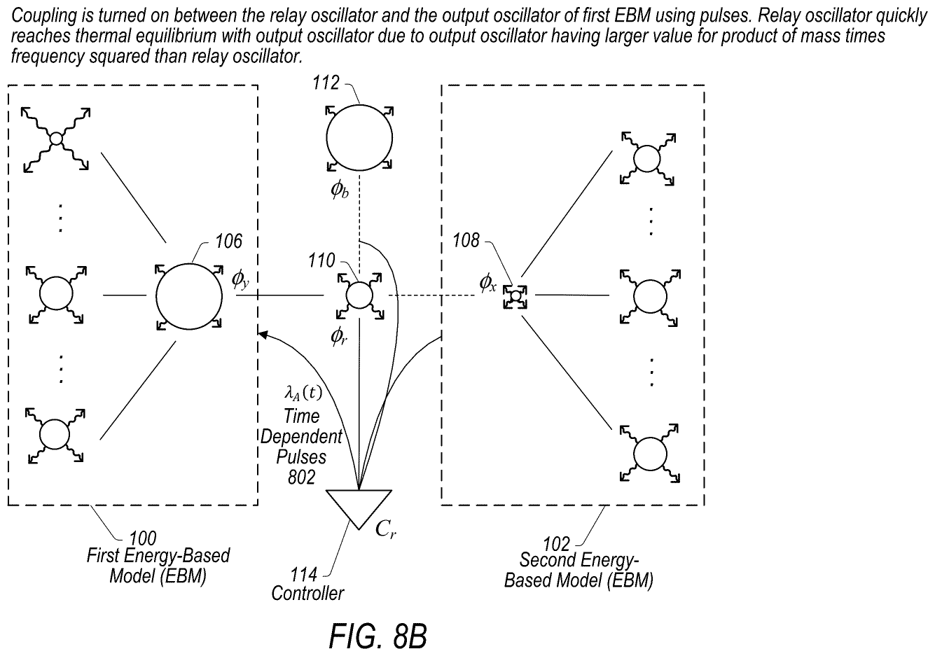

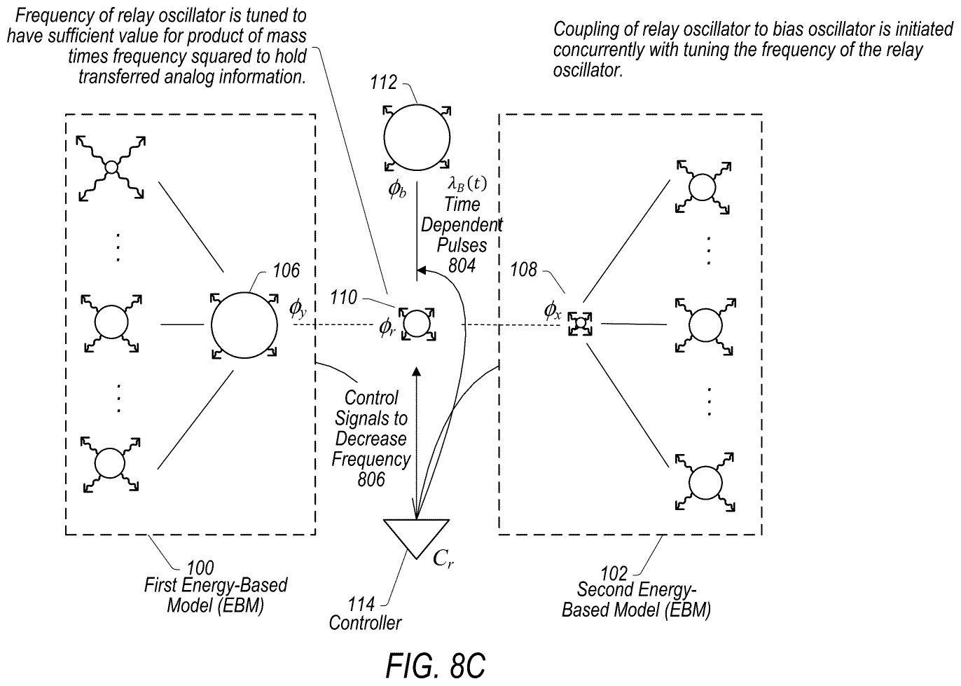

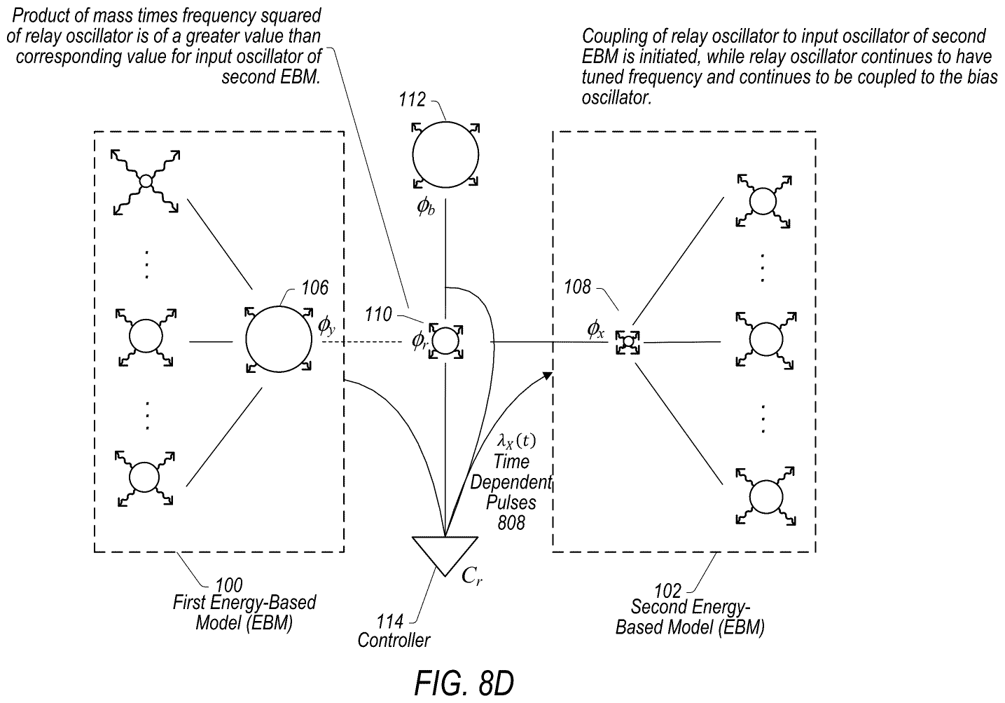

Controller 114 also causes time dependent pulses 604 to be emitted to couple the relay oscillator 110 to the bias oscillator 112 and concurrently causes control signals 606 to be provided, for example to a Cooper-pair box, as shown in FIG. 5, in order to cause the mass of the relay oscillator 110 to be increased. Note that in some embodiments, turning on the coupling between the relay oscillator 110 and the bias oscillator 112 may be performed concurrently with turning on the coupling between the relay oscillator 110 and the input oscillator 108 of the second EBM (as shown in FIG. 8D). Also in some embodiments, the coupling between the relay oscillator 110 and the bias oscillator 112 may be turned on prior to coupling the relay oscillator to the input oscillator 108 of the second EBM.

FIG. 6D is a conceptual diagram illustrating relative masses and frequencies of oscillators of the first energy-based model (EBM), relative masses and frequencies of oscillators of the second energy-based model (EBM), and relative masses and frequencies of oscillators of the relay gadget, at a next stage of a relay process, wherein coupling is activated between the relay oscillator and the input oscillator of the second energy-based model (EBM), according to some embodiments.

Finally, the controller 114 causes time-dependent pulses 608 to be emitted to couple the relay oscillator 110 to the input oscillator 108, thus relaying thermal information (in analog form) from output oscillator 106 to input oscillator 108. Note that once the mass of the relay oscillator is increased, such as shown in FIG. 6C, the mass may remain increased, such that the relay oscillator has a larger value of a product of mass times frequency squared than a corresponding value for the input oscillator 108. In some embodiments, the coupling of the relay oscillator 110 to the input oscillator 108 may be performed at the same time as turning on the coupling between the relay oscillator 110 and the bias oscillator 112.

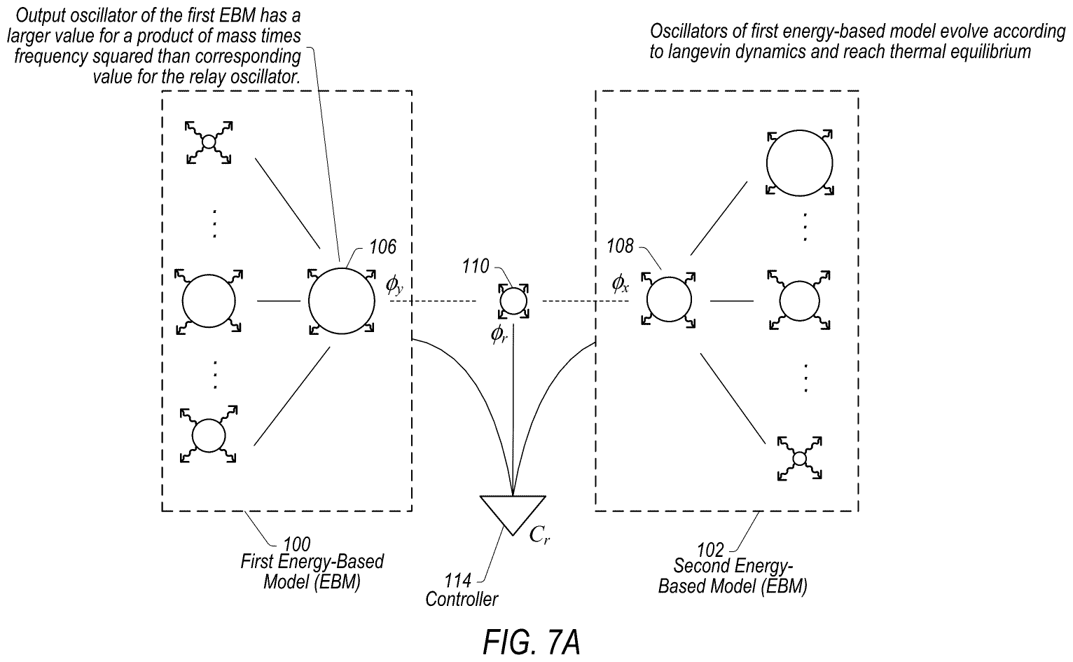

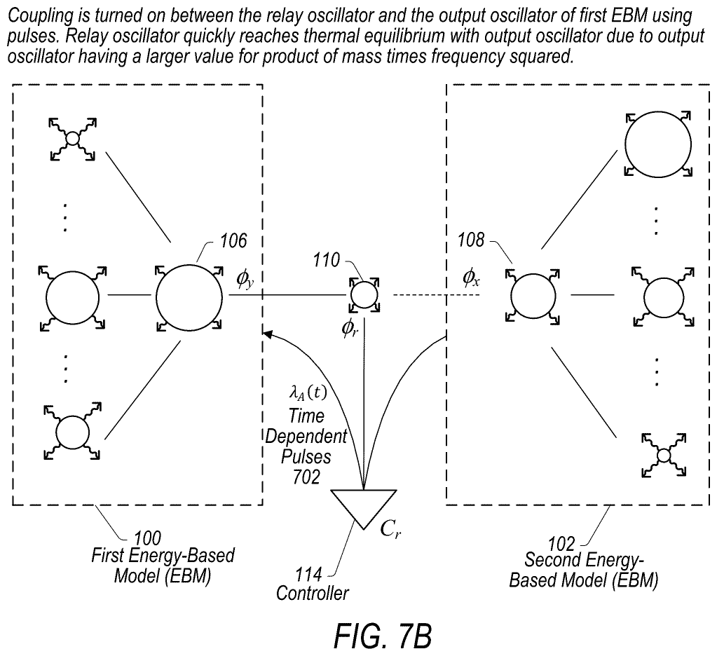

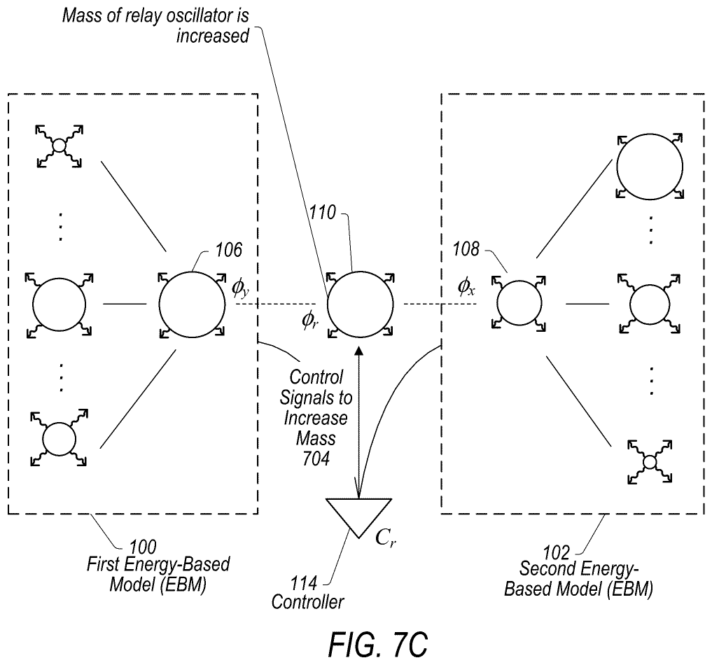

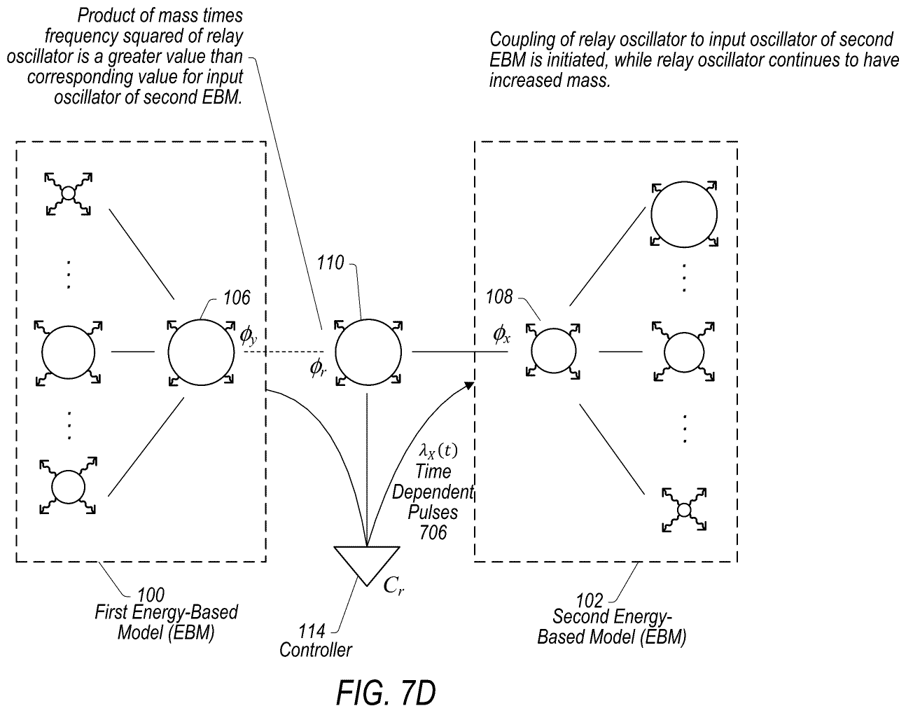

FIG. 7A is a conceptual diagram illustrating relative masses and frequencies of oscillators of the first energy-based model (EBM), relative masses and frequencies of oscillators of the second energy-based model (EBM), and relative masses and frequencies of oscillators of the relay gadget, at an initial stage of a relay process, prior to coupling the relay oscillator to the output oscillator of the first energy-based model (EBM), according to some embodiments.

As discussed above, in some embodiments, a bias oscillator may not be used. For example, increasing the mass of relay oscillator 110 may be sufficient for relay oscillator to hold analog thermodynamic information received from output oscillator 106 without the need for a bias oscillator. Also, as can be seen in FIG. 7A, output oscillator 106 has a larger value of mass times frequency squared than a corresponding value for input oscillator 108. Thus, relay oscillator can be initialized to have a value of mass times frequency squared that is less than that of output oscillator 106, which allows for the analog thermodynamic information to be exchanged from output oscillator 106 to relay oscillator 110. However, relay oscillator 110's mass is later increased, such that at a subsequent moment in time relay oscillator 100 has a larger value of mass times frequency squared than a corresponding value of mass times frequency squared for input oscillator 108. Thus, after the mass is increased, relay oscillator is configured to transfer the received analog thermodynamic information to input oscillator 108.

FIG. 7B is a conceptual diagram illustrating relative masses and frequencies of oscillators of the first energy-based model (EBM), relative masses and frequencies of oscillators of the second energy-based model (EBM), and relative masses and frequencies of oscillators of the relay gadget, at a subsequent stage of a relay process, wherein coupling is activated between the relay oscillator and the output oscillator of the first energy-based model (EBM), according to some embodiments.

Controller 114 causes time dependent pulses 702 to be emitted, which cause output oscillator 106 to be coupled to relay oscillator 110.

FIG. 7C is a conceptual diagram illustrating relative masses and frequencies of oscillators of the first energy-based model (EBM), relative masses and frequencies of oscillators of the second energy-based model (EBM), and relative masses and frequencies of oscillators of the relay gadget, at another stage of a relay process, wherein the mass of the relay oscillator is increased, according to some embodiments.

Controller 114 also causes control signals 704 to be provided, for example to a Cooper-pair box, as shown in FIG. 5, in order to cause the mass of the relay oscillator 110 to be increased.

FIG. 7D is a conceptual diagram illustrating relative masses and frequencies of oscillators of the first energy-based model (EBM), relative masses and frequencies of oscillators of the second energy-based model (EBM), and relative masses and frequencies of oscillators of the relay gadget, at a next stage of a relay process, wherein coupling is activated between the relay oscillator and the input oscillator of the second energy-based model (EBM), according to some embodiments.

Finally, the controller 114 causes time-dependent pulses 706 to be emitted to couple the relay oscillator 110 to the input oscillator 108, thus relaying thermal information (in analog form) from output oscillator 106 to input oscillator 108. Note that once the mass of the relay oscillator is increased, such as shown in FIG. 7C, the mass may remain increased, such that the relay oscillator has a larger value of a product of mass times frequency squared than a corresponding value for the input oscillator 108.

FIG. 8A is a conceptual diagram illustrating relative masses and frequencies of oscillators of the first energy-based model (EBM), relative masses and frequencies of oscillators of the second energy-based model (EBM), and relative masses and frequencies of oscillators of the relay gadget, at an initial stage of a relay process, prior to coupling the relay oscillator to the output oscillator of the first energy-based model (EBM), according to some embodiments.

As discussed above, initially the relay oscillator 110 may have a smaller value for a product of mass times frequency squared as compared to a respective value of mass times frequency squared for the output oscillator 106. In FIG. 8A the size of the respective circles illustrating the oscillators are used to show relative masses of the oscillators. Also, the arrows coming out from the circles are used to illustrate the motion (e.g. frequency) of the oscillators. In some embodiments, instead of increasing the mass of the relay oscillator, the frequency may be increased.

FIG. 8B is a conceptual diagram illustrating relative masses and frequencies of oscillators of the first energy-based model (EBM), relative masses and frequencies of oscillators of the second energy-based model (EBM), and relative masses and frequencies of oscillators of the relay gadget, at a subsequent stage of a relay process, wherein coupling is activated between the relay oscillator and the output oscillator of the first energy-based model (EBM), according to some embodiments.

Controller 114 causes time dependent pulses 802 to be emitted, which cause output oscillator 106 to be coupled to relay oscillator 110.

FIG. 8C is a conceptual diagram illustrating relative masses and frequencies of oscillators of the first energy-based model (EBM), relative masses and frequencies of oscillators of the second energy-based model (EBM), and relative masses and frequencies of oscillators of the relay gadget, at another stage of a relay process, wherein coupling is activated between the relay oscillator and the bias oscillator, and wherein the frequency of the relay oscillator is tuned (e.g., decreased in this example), according to some embodiments.

Controller 114 also causes time dependent pulses 804 to be emitted to couple the relay oscillator 110 to the bias oscillator 112 and concurrently causes control signals 806 to be provided, for example to a current inducing flux element, as shown in FIG. 4, in order to cause the frequency of the relay oscillator 110 to be decreased. Note that in some embodiments, turning on the coupling between the relay oscillator 110 and the bias oscillator 112 may be performed concurrently with turning on the coupling between the relay oscillator 110 and the input oscillator 108 of the second EBM (as shown in FIG. 8D). Also in some embodiments, the coupling between the relay oscillator 110 and the bias oscillator 112 may be turned on prior to coupling the relay oscillator to the input oscillator 108 of the second EBM.

FIG. 8D is a conceptual diagram illustrating relative masses and frequencies of oscillators of the first energy-based model (EBM), relative masses and frequencies of oscillators of the second energy-based model (EBM), and relative masses and frequencies of oscillators of the relay gadget, at a next stage of a relay process, wherein coupling is activated between the relay oscillator and the input oscillator of the second energy-based model (EBM), according to some embodiments.

Finally, the controller 114 causes time-dependent pulses 808 to be emitted to couple the relay oscillator 110 to the input oscillator 108, thus relaying thermal information (in analog form) from output oscillator 106 to input oscillator 108. In some embodiments, the coupling of the relay oscillator 110 to the input oscillator 108 may be performed at the same time as turning on the coupling between the relay oscillator 110 and the bias oscillator 112.

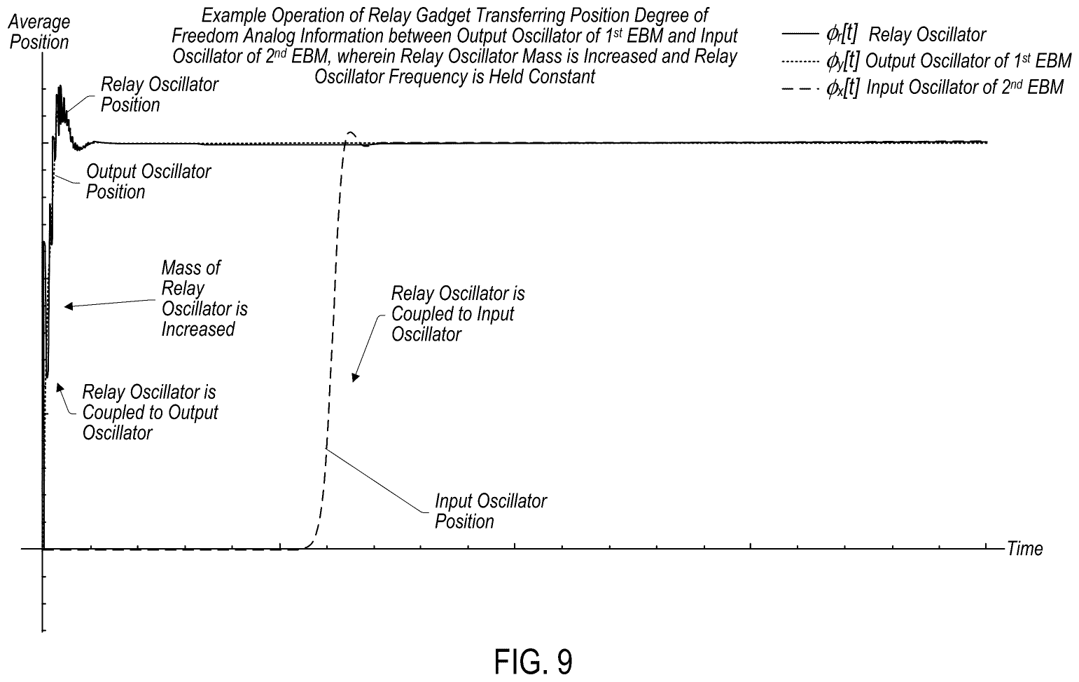

FIG. 9 is an example chart illustrating effects of coupling an input oscillator degree of freedom (e.g. position) to a relay oscillator degree of freedom (e.g. position), and subsequently coupling the relay oscillator degree of freedom to an output oscillator degree of freedom (e.g. position), wherein a mass of the relay oscillator is adjusted during the relay process, according to some embodiments.

The plot in FIG. 9 shows results of the equations of motion for the output oscillator, input oscillator, and relay oscillator. In this example illustration, the following parameters are used: γ=1, k_{B}=8.8, t₁^{(B)}=33, λ₀^{(B)}(8)=−1.97, M_{B}=221.91, kᵣ=10, tᵣ=33, mᵣ=0.06, ωᵣ(t)=0.01, m_{f}^{(r)}=500, m_{b}=1000, ω_{b}=10, λ_{X}=−0.01, k_{X}=1, T₁^{(X)}=60, λ₀^{(X)}=0, mₓ=0.01, ωₓ=1, m_{y}=1, ω_{y}=1, y_{c}=3, λ_{A}=10, t₁=1, t₂=30, and k_{A}=1.

As can be seen, the coupling between the relay oscillator and the output oscillator is turned on by the controller. Initially the relay oscillator starts out with a combination mass/frequency that is much less than that of the output oscillator. This ensures that the relay oscillator converges to the equilibrium value of the output oscillator when the time dependent pulses are emitted that couple the relay oscillator to the output oscillator. Next, as the coupling between the relay oscillator and the output oscillator is turned off, the controller (optionally) emits pulses to couple the relay oscillator to the bias oscillator. Simultaneously, the controller causes the mass of the relay oscillator to be increased. Increasing the mass of the relay oscillator ensures that when the relay oscillator is coupled to the input oscillator, the average position of the relay oscillator can be treated as a constant (e.g., the coupling of the relay oscillator to the input oscillator does not change the position of the relay oscillator). The coupling of the relay oscillator to the bias oscillator may remain turned on, for example while the relay oscillator is coupled to the input oscillator.

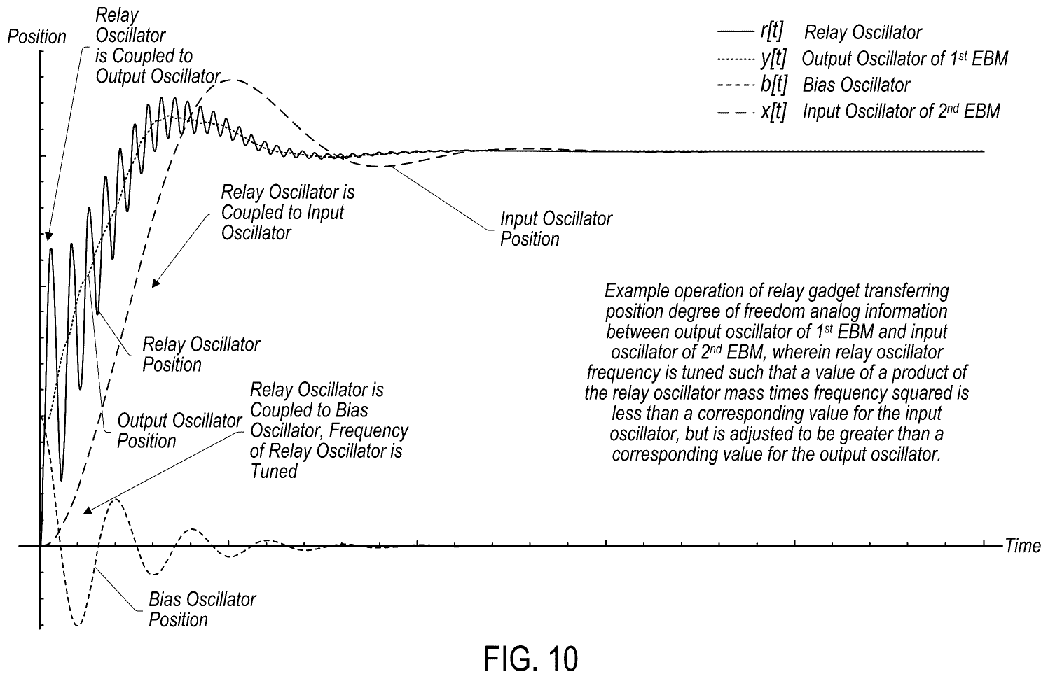

FIG. 10 is an example chart illustrating effects of coupling an output oscillator degree of freedom (e.g. position) to a relay oscillator degree of freedom (e.g. position), and subsequently coupling the relay oscillator degree of freedom to an input oscillator degree of freedom (e.g. position), wherein a frequency of the relay oscillator is adjusted during the relay process, according to some embodiments.

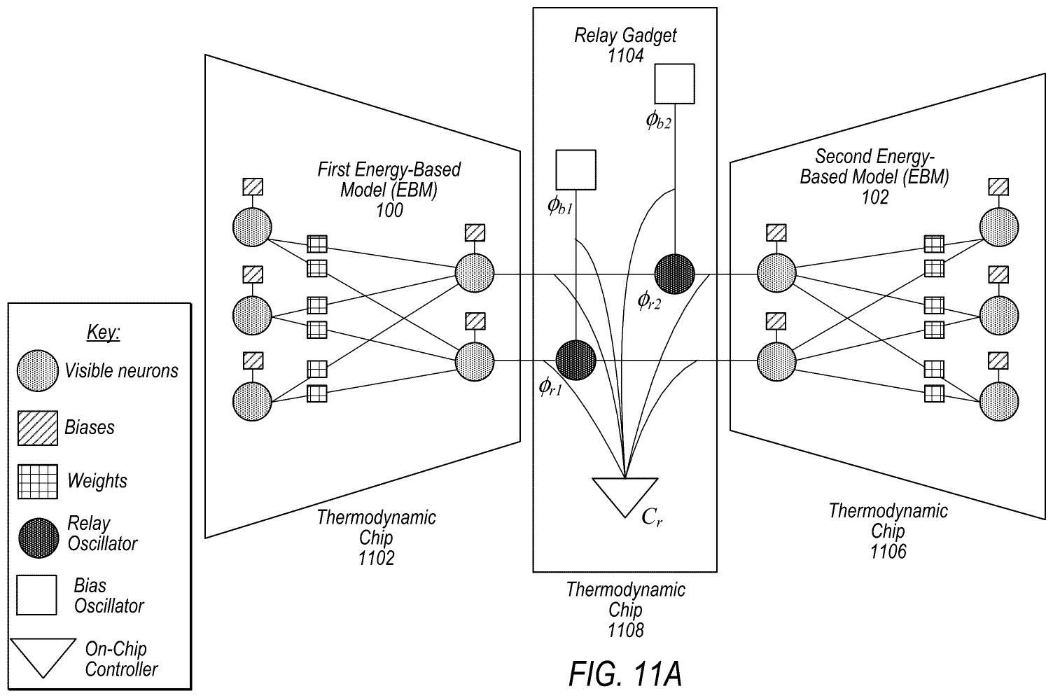

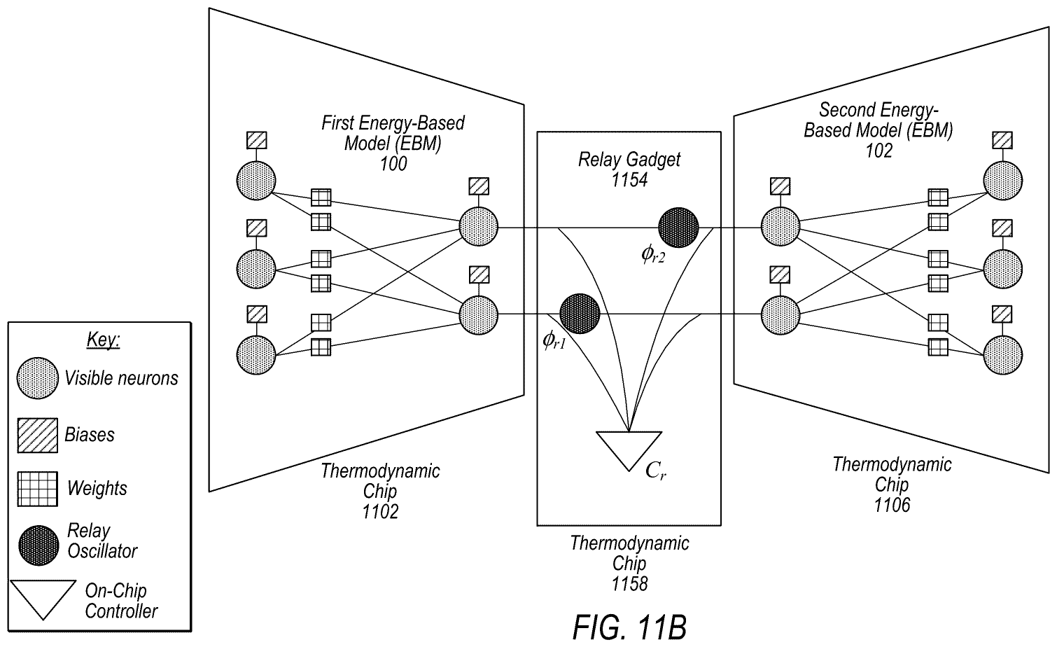

FIG. 11A illustrates an example configuration, wherein the first energy-based model (EBM), the second energy-based model (EBM) and the relay gadget are implemented using oscillators of different thermodynamic chips, according to some embodiments.

In some embodiments, the first energy-based model 100, the second energy-based model 102, and the relay gadget 104 may be implemented at least in part on different thermodynamic chips. For example, in FIG. 11A, energy-based model 100 is implemented on thermodynamic chip 1102, energy-based model 102 is implemented on thermodynamic chip 1106, and relay gadget 104 is implemented on thermodynamic chip 1108.

FIG. 11B illustrates an example configuration similar to that of FIG. 11A, wherein the relay gadget does not include a bias oscillator, according to some embodiments.

For example, in FIG. 11B relay gadget 1154 is implemented on thermodynamic chip 1158 and does not include bias oscillators.

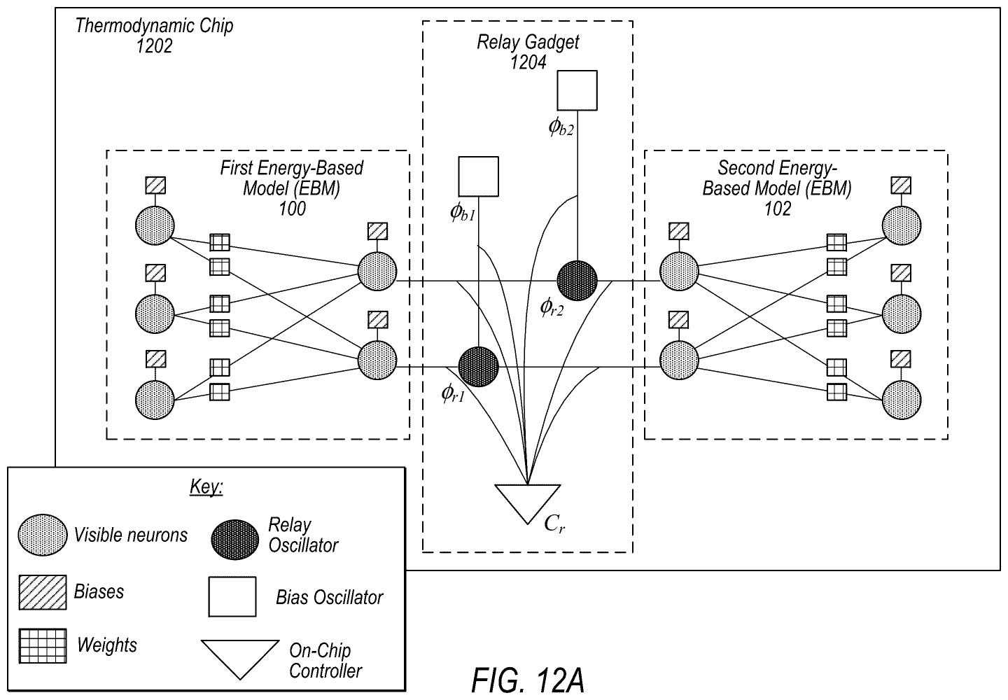

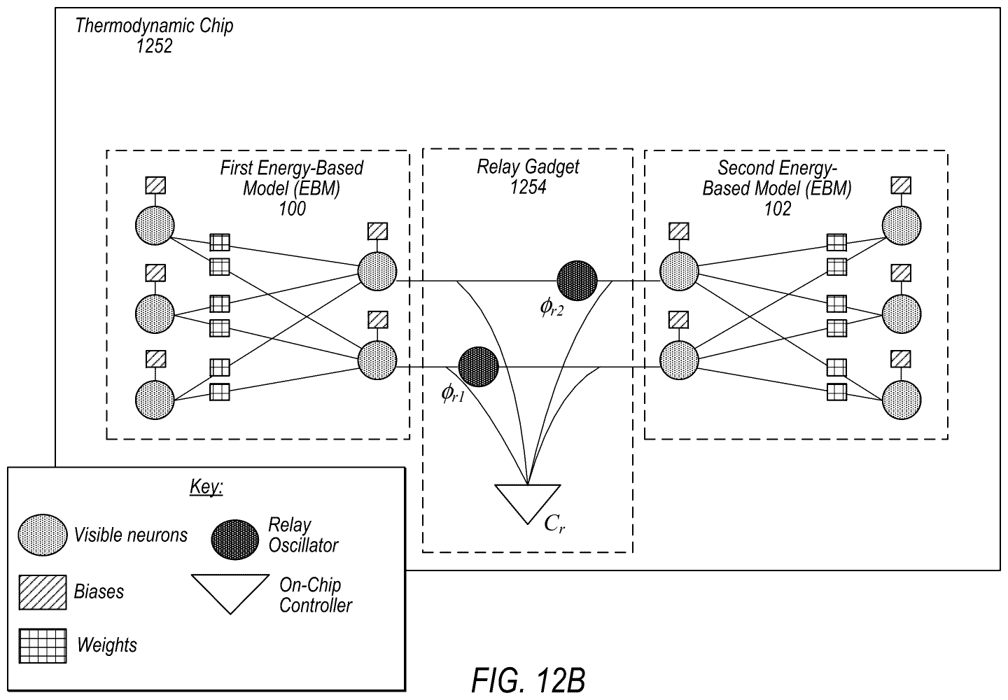

FIG. 12A illustrates an example configuration, wherein the first energy-based model (EBM), the second energy-based model (EBM) and the relay gadget are implemented using oscillators of a single thermodynamic chip, according to some embodiments.

In some embodiments multiple energy-based models and/or relay gadgets may be implemented using oscillators of a same thermodynamic chip. For example, in FIG. 12A, a single thermodynamic chip 1202 implements energy-based model 100, energy-based model 102, and relay gadget 104.

FIG. 12B illustrates an example configuration similar to that of FIG. 12A, wherein the relay gadget does not include a bias oscillator, according to some embodiments.

For example, relay gadget 1254 implemented on thermodynamic chip 1252 does not include bias oscillators.

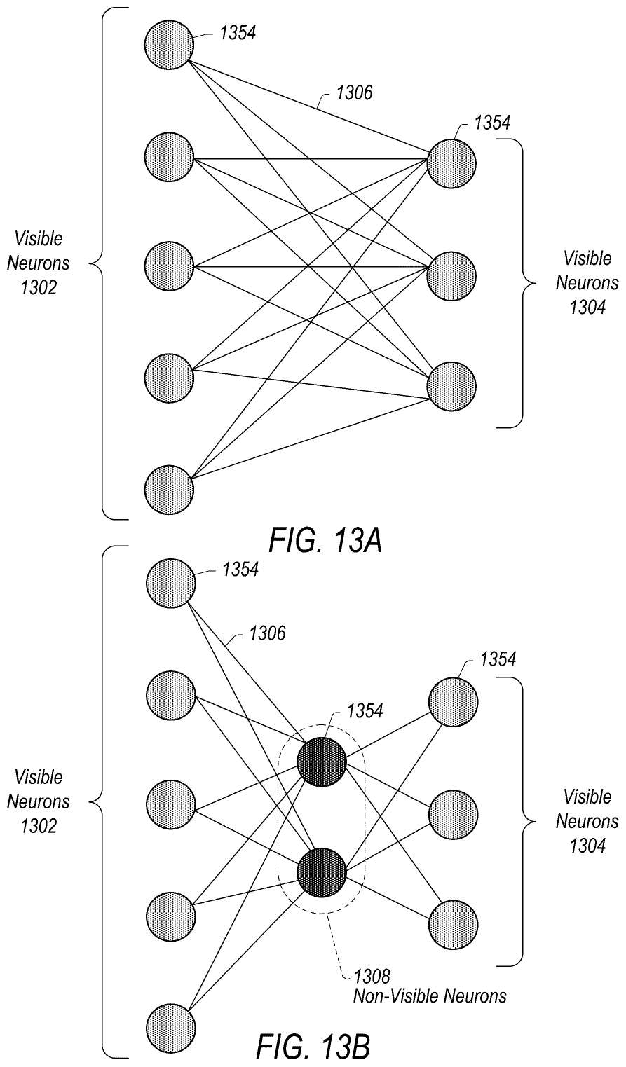

FIG. 13A illustrates example couplings between visible neurons of an energy-based model (EBM), according to some embodiments.

In some embodiments, input neurons and output neurons of an energy-based model, such as visible neurons 1302 and visible neurons 1304, may be directly linked via connected edges 1306. As shown in FIG. 13A, a given visible neuron 1302 of the five shown in the figure is connected, via edges 1306, to each of the respective three visible neurons 1304. A person having ordinary skill in the art should understand that FIG. 13A is meant to represent example embodiments of a graph architecture implemented using a thermodynamic chip that may be applied and that specific numbers of visible neurons 1302 and/or visible neurons 1304 shown in the figure are not meant to be restrictive. Additional configurations combining more/less visible neurons 1302 and/or visible neurons 1304 are also encompassed by the discussion herein. In addition, recall that neurons are logical representations of physical oscillators, such that, when describing neurons in FIGS. 13A and 13B, it should be understood that neurons and edges are implemented using oscillators and couplings.

FIG. 13B illustrates example couplings between visible neurons and non-visible neurons (e.g., hidden neurons) of an energy-based model (EBM), according to some embodiments.

In some embodiments, FIG. 13B may resemble additional example embodiments of an energy-based model architecture implemented using a thermodynamic chip. As shown in the figure, additional non-visible neurons 1308 may be used, which are respectively coupled, via edges 1306, to both visible neurons 1302 and to visible neurons 1304. Note that while the non-visible neurons are “not visible” from the perspective of inputs and outputs, the non-visible neurons may each correspond to a given oscillator. In addition, it may be noted that, in some embodiments that make use of non-visible neurons, no direct connections, via edges 1306, may be implemented between visible neurons 1302 and visible neurons 1304, but rather connections are routed firstly via non-visible neurons 1308, as shown in FIG. 13B. Couplings between visible and non-visible neurons may be additionally referred to herein as “layers” of a given energy-based model architecture that is implemented using a thermodynamic chip, according to some embodiments.

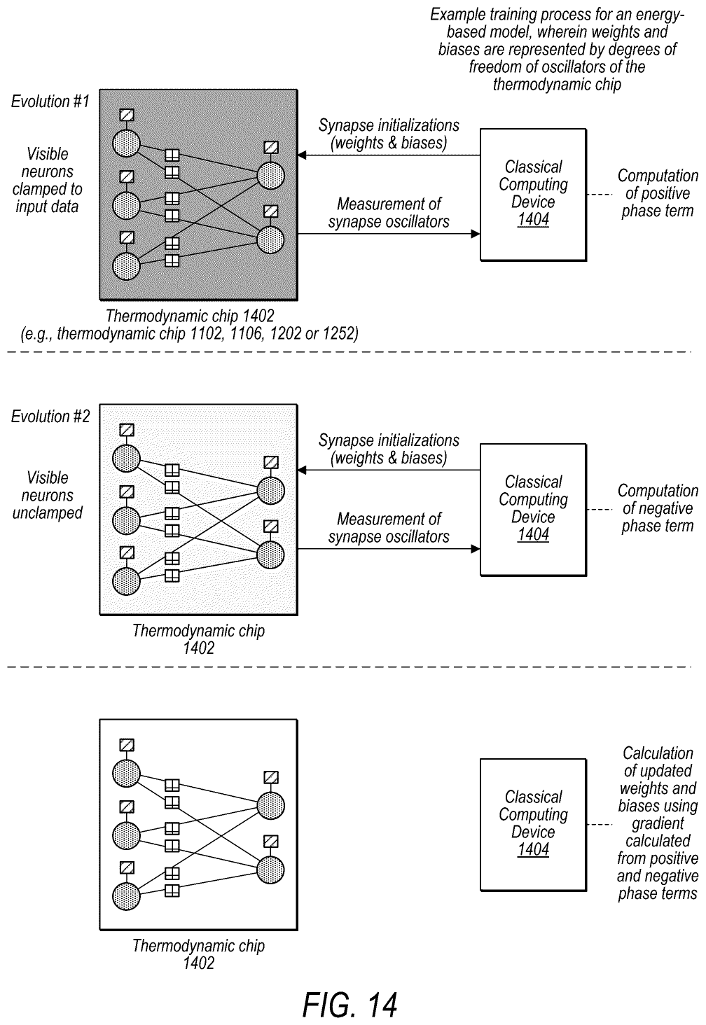

FIG. 14 is high-level diagram illustrating a process of determining weights and biases to be used in an energy-based model (EBM), wherein the weights and biases are determined using measurement values for synapse oscillators, according to some embodiments.

As shown in FIG. 14, in a first evolution, visible neurons of thermodynamic chip 1402 may be clamped to input data. For example, multiple mini-batches of input data may be clamped to visible neurons for multiple evolutions used to generate a first set of measurements used to compute a positive phase term. For example, the measurements may be used by classical computing device 1404 to compute the positive phase term.

Also, in a second (or other subsequent) evolution, the visible neurons may remain unclamped, such that the visible neuron oscillators are free to evolve along with the synapse oscillators during the second (or other subsequent) evolution. Measurements may also be taken and used by the classical computing device 1404 to compute a negative phase term.

Additionally, the positive and negative phase terms computed based on the first and second sets of measurements (e.g., clamped measurements and un-clamped measurements) may be used to calculate updated weights and biases.

This process may be repeated, with the determined updated weights and biases used as initial weights and biases for a subsequent iteration. In some embodiments, inferences generated using the updated weights and biases may be compared to training data to determine if the energy-based model has been sufficiently trained. If so, the model may transition into a mode of performing inferences using the learned weights and biases. If not sufficiently trained, the process may continue with additional iterations of determining updated weights and biases.

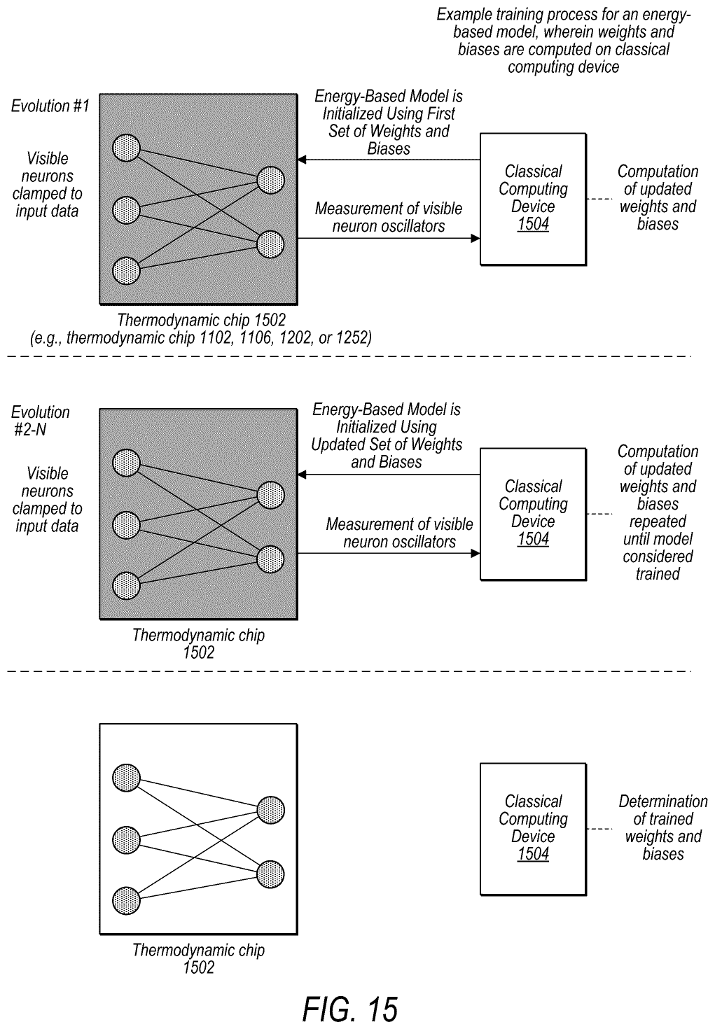

FIG. 15 is high-level diagram illustrating a process of determining weights and biases to be used in an energy-based model (EBM), wherein the weights and biases are computed using a classical computing device, according to some embodiments.

In some embodiments, updated weights and bias values may be computed iteratively by classical computing device 1504 based on inference measurements from thermodynamic chip 1502. For example, inference values may be compared to training data values, and new weights and biases may be iteratively computed until the inference values closely correspond to the training data. As can be seen in FIG. 15, in some embodiments the synapse oscillator may be omitted as degrees of freedom of the energy-based model. For example, when a classical computing device is used to iteratively determine the weight and bias values.

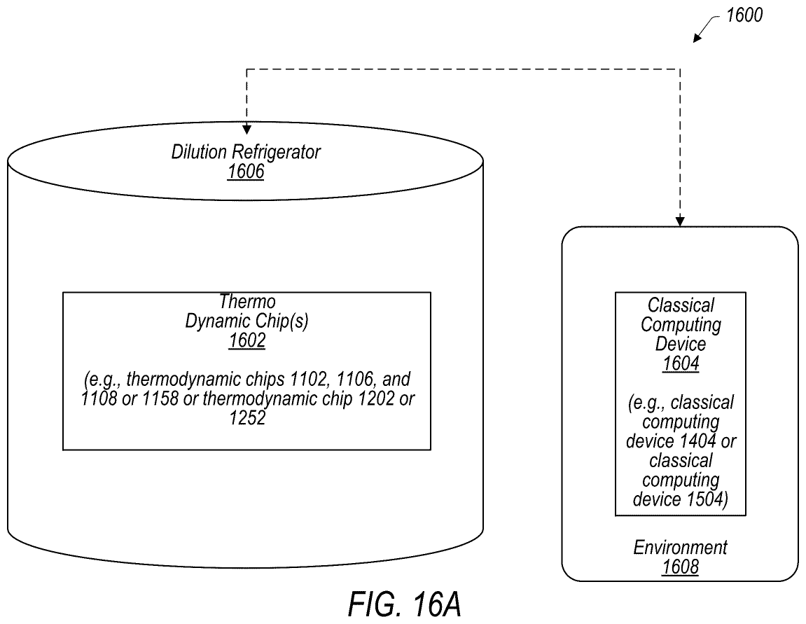

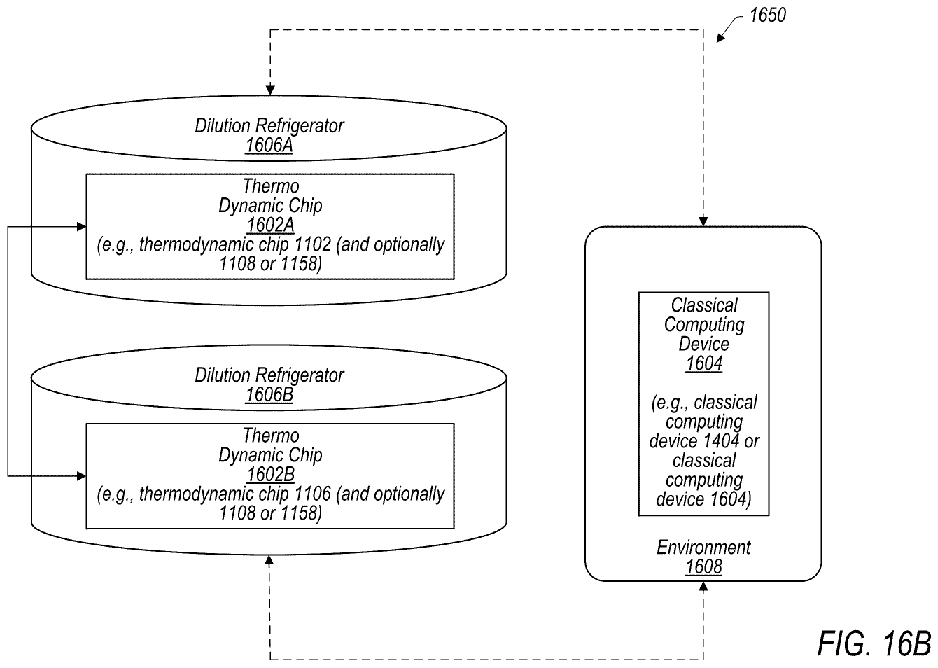

FIG. 16A is high-level diagram illustrating an example neuro-thermodynamic computer comprising a thermodynamic chip (e.g., that implements multiple energy-based models (EBMs) and a relay gadget) included in a dilution refrigerator and coupled to a classical computing device in an environment external to the dilution refrigerator, according to some embodiments.

In some embodiments, a neuro-thermodynamic computing system 1600 (as shown in FIG. 16A) may be used to implement the various embodiments shown in FIGS. 1-15 and may include one or more thermodynamic chip(s) 1602 placed in a dilution refrigerator 1606. In some embodiments, classical computing device 1604 may control temperature for dilution refrigerator 1606, and/or perform other tasks, such as helping to drive a pulse drive to change respective hyperparameters of the given system and/or perform measurements, such as those shown in FIGS. 1-15. Also, the classical computing device 1604 may perform other simple computing operations, such as are needed to determine updated weights and biases.

In some embodiments, classical computing device 1604 may include one or more devices such as a field-programmable gate array (FPGA), an application specific integrated circuit (ASIC), and/or other devices that may be configured to interact and/or interface with a thermodynamic chip within the architecture of neuro-thermodynamic computer 1600. For example, such devices may be used to tune hyperparameters of the given thermodynamic system, etc. as well as perform part of the calculations necessary to determine updated weights and biases. In some embodiments, the classical computing device 1604 may be placed in an environment 1606 outside of the dilution refrigerator 1606.

As shown in FIG. 16A, in embodiments where more than one thermodynamic chip is used with a relay gadget, multiple ones of the thermodynamic chips and the relay gadget may be placed in the same dilution refrigerator 1606.

FIG. 16B is high-level diagram illustrating an example neuro-thermodynamic computer comprising multiple thermodynamic chips (e.g., that implement respective energy-based models (EBMs) and a relay gadget) included in multiple dilution refrigerators and coupled to a classical computing device in an environment external to the dilution refrigerators, according to some embodiments.

Also, in some embodiments, such as shown in FIG. 16B, a neuro-thermodynamic computing system 1650 may be implemented using multiple thermodynamic chips (e.g. thermodynamic chips 1602A and 1602B) that are placed in more than one dilution refrigerator (e.g. dilution refrigerators 1606A and 1606B).

17A is high-level diagram illustrating an example neuro-thermodynamic computer comprising a thermodynamic chip (e.g., that implements multiple energy-based models (EBMs) and a relay gadget) included in a dilution refrigerator and coupled to a classical computing device that is also included in the dilution refrigerator, according to some embodiments.

As another alternative, in some embodiments, a classical computing device used in a neuro-thermodynamic computer, such as in neuro-thermodynamic computer 1700, may be included in a dilution refrigerator with the thermodynamic chip. For example, neuro-thermodynamic computer 1700 includes both thermodynamic chip 1702 and classical computing device 1704 in dilution refrigerator 1706.

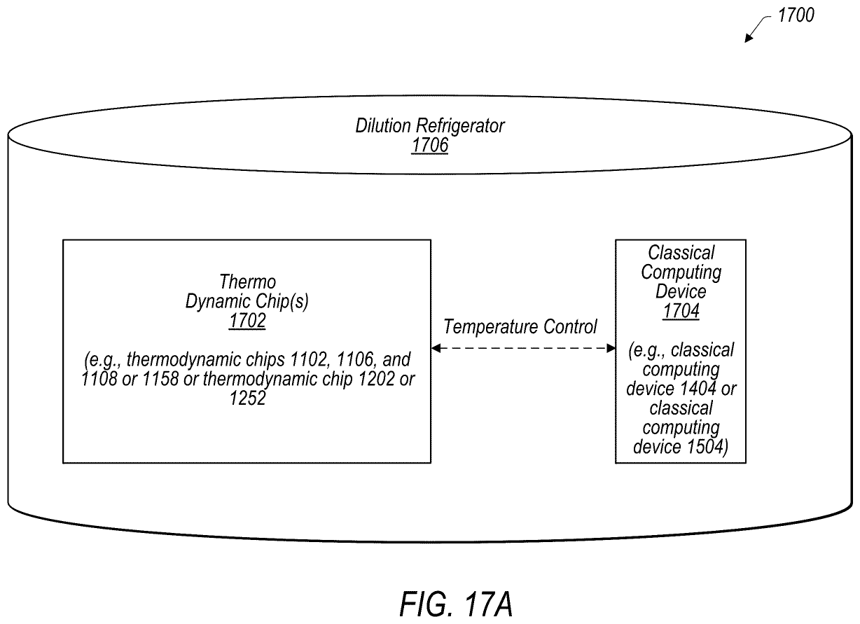

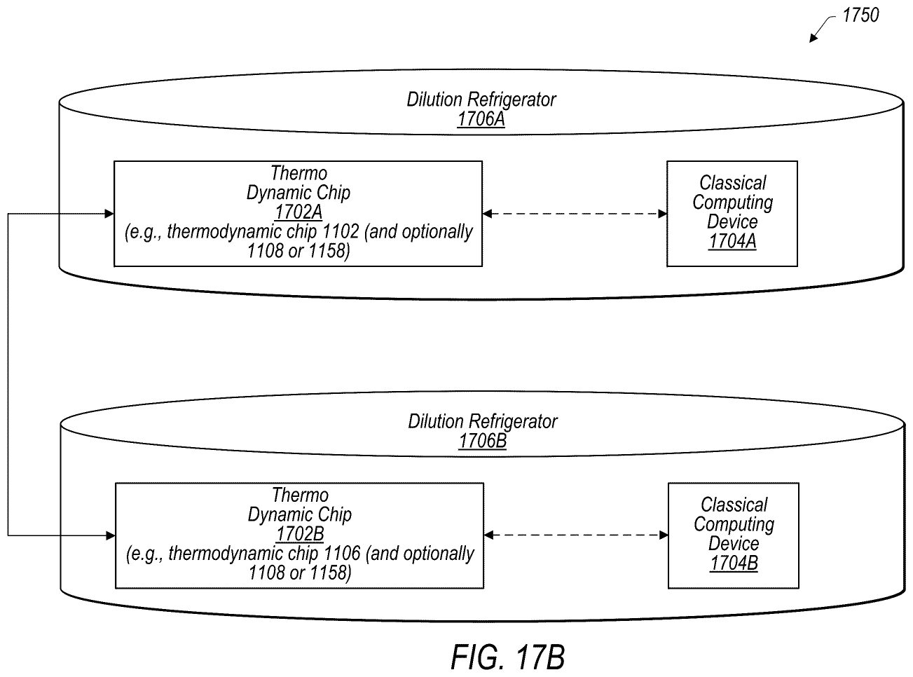

FIG. 17B is high-level diagram illustrating an example neuro-thermodynamic computer comprising multiple thermodynamic chips (e.g., that implement respective energy-based models (EBMs) and a relay gadget) included in respective dilution refrigerators and coupled to respective classical computing devices that are also included in the respective dilution refrigerators, according to some embodiments.

Also, in some embodiments, a similar configuration as shown in FIG. 17A may be used, however the thermodynamic chips may be included in more than one dilution refrigerator. For example, thermodynamic chips 1702A and 1702B may be included in dilution refrigerators 1706A and 1706B, respectively.

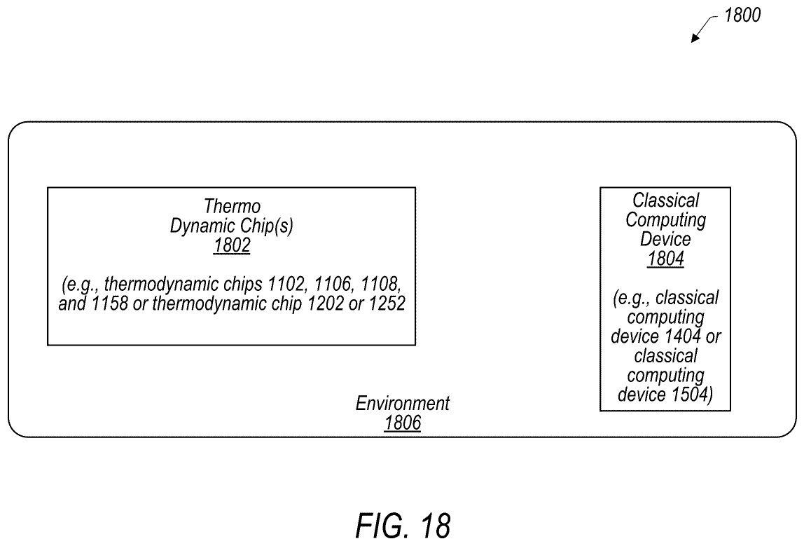

FIG. 18 is high-level diagram illustrating an example neuro-thermodynamic computer comprising one or more thermodynamic chips (e.g., that implement respective energy-based models (EBMs) and a relay gadget) coupled to a classical computing device in an environment other than a dilution refrigerator, according to some embodiments.

Also, in some embodiments, a neuro-thermodynamic computer, such as neuro-thermodynamic computer 1800, may be implemented in an environment other than a dilution refrigerator. For example, neuro-thermodynamic computer 1800 includes thermodynamic chip(s) 1802 and classical computing device 1804, in environment 1806. In some embodiments, environment 1806 may be temperature controlled and, the classical computing device (or other device) may control the temperature of environment 1806 in order to achieve a given level of evolution according to Langevin dynamics.

FIG. 19 is a high-level diagram illustrating oscillators included in a substrate of the thermodynamic chip and mapping of the oscillators to logical neurons of the thermodynamic chip, according to some embodiments.

In some embodiments, a substrate 1902 may be included in a thermodynamic chip, such as any one of the thermodynamic chips described above. Oscillators 1904 of substrate 1902 may be mapped in a logical representation 1952 to neurons 1954, as well as weights and biases (shown in FIG. 20). In some embodiments, oscillators 1904 may include oscillators with potentials ranging from a single well potential to a dual-well potential and may be mapped to visible neurons, weights, and biases.

In some embodiments, Josephson junctions and/or superconducting quantum interference devices (SQUIDS) may be used to implement and/or excite/control the oscillators 1904. In some embodiments, the oscillators 1904 may be implemented using superconducting flux elements (e.g., qubits). In some embodiments, the superconducting flux elements may physically be instantiated using a superconducting circuit built out of coupled nodes comprising capacitive, inductive, and Josephson junction elements, connected in series or parallel, such as shown in FIG. 19 for oscillator 1904. However, in some embodiments, generally speaking various non-linear flux loops may be used to implement the oscillators 1904, such as those having single-well potential, double-well potential, or various other potentials, such as a potential somewhere between a single-well potential and a double-well potential.

FIG. 20 is an additional high-level diagram illustrating oscillators included in a substrate of the thermodynamic chip mapped to logical neurons, weights, and biases of a given neuro-thermodynamic computing system, according to some embodiments.

While weights and biases are not shown in FIG. 19 for ease of illustration, respective ones of the visible neurons 1954 of FIG. 19 may each have an associated bias, and edges connecting the neurons 1954 may have associated weights. For example, FIGS. 11-12 and 14-15 illustrate an arrangement of five visible neurons along with associated weights and biases. Each of the weights and biases may be mapped to oscillators in the thermodynamic chip, as well as the visible (and non-visible) neurons being mapped to oscillators in the thermodynamic chip. For example, FIG. 20 shows a portion of a thermodynamic chip, wherein weights and biases associated with a given neuron 2054 are shown. For example, bias 2056 may be a bias value for visible neuron 2054 and weights 2058 and 2060 may be weights for edges formed between visible neuron 2054 and other visible neurons of the thermodynamic chip. As shown in FIG. 20, each of the chip elements (visible neuron 2054, bias 2056, weight 2058, and weight 2060) may be mapped to separate ones of oscillators 2004. This may allow the visible neurons (and/or hidden neurons), weights, and biases to have independent degrees of freedom within a given thermodynamic chip that can separately evolve.

In some embodiments, oscillators associated with weights and biases, such as bias 2056 and weights 2058 and 2060, may be allowed to evolve during a training phase and may be held nearly constant during an inference phase. For example, in some embodiments, larger “masses” may be used for the weights and biases such that the weights and biases evolve more slowly than the visible neurons. This may have the effect of holding the weight values and the bias values nearly constant during an evolution phase used for generating inference values.

### Illustrative Computer System

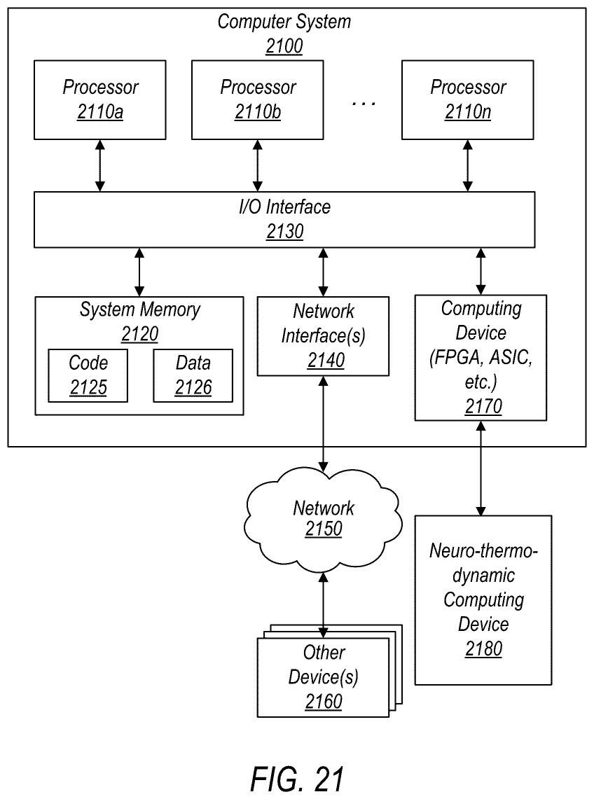

FIG. 21 is a block diagram illustrating an example computer system that may be used in at least some embodiments. In some embodiments, the computing system shown in FIG. 21 may be used, at least in part, to implement any of the techniques described above in FIGS. 1-20. Furthermore, computer system 2100 may be configured to interact and/or interface with neuro-thermodynamic computing device 2180, according to some embodiments.

In the illustrated embodiment, computer system 2100 includes one or more processors 2110 coupled to a system memory 2120 (which may comprise both non-volatile and volatile memory modules) via an input/output (I/O) interface 2130. Computer system 2100 further includes a network interface 2140 coupled to I/O interface 2130. Classical computing functions may be performed on a classical computer system, such as computing computer system 2100.

Additionally, computer system 2100 includes computing device 2170 coupled to thermodynamic chip 2180. In some embodiments, computing device 2170 may be a field programmable gate array (FPGA), application specific integrated circuit (ASIC) or other suitable processing unit. In some embodiments, computing device 2170 may be a similar computing device as described in FIGS. 1-20, such as classical computing devices used to control a thermodynamic chip. In some embodiments, neuro thermodynamic computing device 2180 may be a similar neuro thermodynamic computing device as described in FIGS. 1-20, such as neuro thermodynamic computing devices implemented using thermodynamic chips.

In various embodiments, computer system 2100 may be a uniprocessor system including one processor 2110, or a multiprocessor system including several processors 2110 (e.g., two, four, eight, or another suitable number). Processors 2110 may be any suitable processors capable of executing instructions. For example, in various embodiments, processors 2110 may be general-purpose or embedded processors implementing any of a variety of instruction set architectures (ISAs), such as the x86, PowerPC, SPARC, or MIPS ISAs, or any other suitable ISA. In multiprocessor systems, each of processors 2110 may commonly, but not necessarily, implement the same ISA. In some implementations, graphics processing units (GPUs) may be used instead of, or in addition to, conventional processors.

System memory 2120 may be configured to store instructions and data accessible by processor(s) 2110. In at least some embodiments, the system memory 2120 may comprise both volatile and non-volatile portions; in other embodiments, only volatile memory may be used. In various embodiments, the volatile portion of system memory 2120 may be implemented using any suitable memory technology, such as static random-access memory (SRAM), synchronous dynamic RAM or any other type of memory. For the non-volatile portion of system memory (which may comprise one or more NVDIMMs, for example), in some embodiments flash-based memory devices, including NAND-flash devices, may be used. In at least some embodiments, the non-volatile portion of the system memory may include a power source, such as a supercapacitor or other power storage device (e.g., a battery). In various embodiments, memristor based resistive random-access memory (ReRAM), three-dimensional NAND technologies, Ferroelectric RAM, magneto resistive RAM (MRAM), or any of various types of phase change memory (PCM) may be used at least for the non-volatile portion of system memory. In the illustrated embodiment, program instructions and data implementing one or more desired functions, such as those methods, techniques, and data described above, are shown stored within system memory 2120 as code 2125 and data 2126.

In some embodiments, I/O interface 2130 may be configured to coordinate I/O traffic between processor 2110, system memory 2120, computing device 2170, and any peripheral devices in the computer system, including network interface 2140 or other peripheral interfaces such as various types of persistent and/or volatile storage devices. In some embodiments, I/O interface 2130 may perform any necessary protocol, timing or other data transformations to convert data signals from one component (e.g., system memory 2120) into a format suitable for use by another component (e.g., processor 2110). In some embodiments, I/O interface 2130 may include support for devices attached through various types of peripheral buses, such as a variant of the Peripheral Component Interconnect (PCI) bus standard or the Universal Serial Bus (USB) standard, for example. In some embodiments, the function of I/O interface 2130 may be split into two or more separate components, such as a north bridge and a south bridge, for example. Also, in some embodiments some or all of the functionality of I/O interface 2130, such as an interface to system memory 2120, may be incorporated directly into processor 2110.

Network interface 2140 may be configured to allow data to be exchanged between computing device 2100 and other devices 2160 attached to a network or networks 2150, such as other computer systems or devices. In various embodiments, network interface 2140 may support communication via any suitable wired or wireless general data networks, such as types of Ethernet network, for example. Additionally, network interface 2140 may support communication via telecommunications/telephony networks such as analog voice networks or digital fiber communications networks, via storage area networks such as Fibre Channel SANs, or via any other suitable type of network and/or protocol.

In some embodiments, system memory 2120 may represent one embodiment of a computer-accessible medium configured to store at least a subset of program instructions and data used for implementing the methods and apparatus discussed in the context of FIG. 1 through FIG. 20. However, in other embodiments, program instructions and/or data may be received, sent or stored upon different types of computer-accessible media. Generally speaking, a computer-accessible medium may include non-transitory storage media or memory media such as magnetic or optical media, e.g., disk or DVD/CD coupled to computer system 2100 via I/O interface 2130. A non-transitory computer-accessible storage medium may also include any volatile or non-volatile media such as RAM (e.g., SDRAM, DDR SDRAM, RDRAM, SRAM, etc.), ROM, etc., that may be included in some embodiments of computer system 2100 as system memory 2120 or another type of memory. In some embodiments, a plurality of non-transitory computer-readable storage media may collectively store program instructions that when executed on or across one or more processors implement at least a subset of the methods and techniques described above. A computer-accessible medium may further include transmission media or signals such as electrical, electromagnetic, or digital signals, conveyed via a communication medium such as a network and/or a wireless link, such as may be implemented via network interface 2140. Portions or all of multiple computing devices such as that illustrated in FIG. 21 may be used to implement the described functionality in various embodiments; for example, software components running on a variety of different devices and servers may collaborate to provide the functionality. In some embodiments, portions of the described functionality may be implemented using storage devices, network devices, or special-purpose computer systems, in addition to or instead of being implemented using general-purpose computer systems. The term “computer system”, as used herein, refers to at least all these types of devices, and is not limited to these types of devices.

### CONCLUSION

Various embodiments may further include receiving, sending or storing instructions and/or data implemented in accordance with the foregoing description upon a computer-accessible medium. Generally speaking, a computer-accessible medium may include storage media or memory media such as magnetic or optical media, e.g., disk or DVD/CD-ROM, volatile or non-volatile media such as RAM (e.g., SDRAM, DDR, RDRAM, SRAM, etc.), ROM, etc., as well as transmission media or signals such as electrical, electromagnetic, or digital signals, conveyed via a communication medium such as network and/or a wireless link.

The various methods as illustrated in the Figures above are described herein represent exemplary embodiments of methods. The methods may be implemented in software, hardware, or a combination thereof. The order of method may be changed, and various elements may be added, reordered, combined, omitted, modified, etc.

It will also be understood that, although the terms first, second, etc., may be used herein to describe various elements, these elements should not be limited by these terms. These terms are only used to distinguish one element from another. For example, a first contact could be termed a second contact, and, similarly, a second contact could be termed a first contact, without departing from the scope of the present invention. The first contact and the second contact are both contacts, but they are not the same contact.

Various modifications and changes may be made as would be obvious to a person skilled in the art having the benefit of this disclosure. It is intended to embrace all such modifications and changes and, accordingly, the above description is to be regarded in an illustrative rather than a restrictive sense.

What is claimed is:

1. A system comprising:
one or more thermodynamic chips, wherein the one or more thermodynamic chips comprise:
a first set of oscillators configured to implement a first energy-based model (EBM);
a second set of oscillators configured to implement a second energy-based model (EBM); and
a third set of oscillators configured to implement a relay gadget for relaying information between the first EBM and the second EBM, wherein the third set of oscillators configured to implement the relay gadget comprises:
a relay oscillator,
wherein the relay gadget is further implemented using an on-chip classical controller of the one or more thermodynamic chips, wherein the on-chip classical controller is configured to:
cause a first set of one or more pulses to be emitted, wherein the first set of pulses couples the relay oscillator to an oscillator of the first EBM;
cause one or more control signals to be emitted to increase a mass of the relay oscillator or to tune a frequency of the relay oscillator, wherein the increase of the mass or the tuning of the frequency of the relay oscillator is performed with the relay oscillator coupled to the bias oscillator;
cause a another set of one or more pulses to be emitted, wherein the other set of pulses couples the relay oscillator to an oscillator of the second EBM.

2. The system of claim 1,
wherein the relay gadget further comprises a bias oscillator, and
wherein the on-chip classical controller is configured to:
cause a second set of one or more pulses to be emitted, wherein the second set of pulses couple the relay oscillator to the bias oscillator, and wherein the second set of pulses are caused to be emitted after the first set of pulses and before the other set of pulses.

3. The system of claim 2, wherein the on-chip classical controller is configured to:
cause the relay oscillator to couple with the bias oscillator concurrently with causing the mass of the relay oscillator to be increased or the frequency of the relay oscillator to be tuned.

4. The system of claim 1, wherein the information relayed between the first EBM and the second EBM, via the relay gadget, comprises analog information for one or more degrees of freedom of the relay oscillator of the first EBM.

5. The system of claim 1, wherein first set of oscillators that implement the first EBM, the second set of oscillators that implement the second EBM, and the third set of oscillators that implement the relay gadget are oscillators of a same thermodynamic chip of the one or more thermodynamic chips.

6. The system of claim 1: wherein:
the first set of oscillators that implement the first EBM are oscillators of a first thermodynamic chip of the one or more thermodynamic chips;
the second set of oscillators that implement the second EBM are oscillators of a second thermodynamic chip of the one or more thermodynamic chips; and
the third set of oscillators that implement the relay gadget are oscillators of the first thermodynamic chip, the second thermodynamic chip, or a third thermodynamic chip of the one or more thermodynamic chips.

7. The system of claim 6, wherein:
the first thermodynamic chip and the second thermodynamic chip are positioned within a same dilution refrigerator.

8. The system of claim 6, wherein:
the first thermodynamic chip and the second thermodynamic chip are positioned within different dilution refrigerators.

9. The system of claim 1, wherein the on-chip classical controller is configured to cause the mass of the relay oscillator to be increased.

10. The system of claim 9, wherein to increase the mass of the relay oscillator, the on-chip classical controller is configured to:
cause the one or more control signals to be emitted to cause a capacitance of a superconducting circuit to change over time in response to the one or more control signals, wherein the superconducting circuit implements the relay oscillator.

11. The system of claim 1, wherein the on-chip classical controller is configured to cause the frequency of the relay oscillator to be tuned.

12. The system of claim 11, wherein to tune the frequency of the relay oscillator, the on-chip classical controller is configured to:
cause the one or more control signals to be emitted to cause an inductance of a superconducting circuit to change over time in response to the one or more control signals, wherein the superconducting circuit implements the relay oscillator, and wherein the inductance of the superconducting circuit is changed by applying a time dependent flux bias to a superconducting quantum interference device (SQUID) coupled with the superconducting circuit being used to implement the relay oscillator.

13. The system of claim 1, wherein a product of mass and frequency squared of the oscillator of the first EBM is greater than a product of mass and frequency squared of the relay oscillator, when coupling is initiated between the relay oscillator and the oscillator of the first EBM.

14. The system of claim 1, wherein:
the first set of one or more pulses couples a position degree of freedom of the relay oscillator to a position degree of freedom of the oscillator of the first EBM; and
the other set of one or more pulses couples the position degree of freedom of the relay oscillator to a position degree of freedom of the oscillator of the second EBM.

15. The system of claim 1, wherein:
the first set of one or more pulses couples a momentum degree of freedom of the relay oscillator to a momentum degree of freedom of the oscillator of the first EBM; and
the other set of one or more pulses couples the momentum degree of freedom of the relay oscillator to a momentum degree of freedom of the oscillator of the second EBM.

16. A thermodynamic relay gadget, comprising:
a relay oscillator; and
a controller configured to:
cause a first set of one or more pulses to be emitted to couple the relay oscillator to a first oscillator;
cause one or more control signals to be emitted to increase a mass of the relay oscillator or to tune a frequency of the relay oscillator; and
cause another set of one or more pulses to be emitted to couple the relay oscillator to a second oscillator.

17. The thermodynamic relay gadget of claim 16, wherein coupling the relay oscillator to the first oscillator and coupling the relay oscillator to the second oscillator comprises:
coupling one or more degrees of freedom of the relay oscillator with one or more degrees of freedom of the first oscillator; and
coupling one or more degrees of freedom of the relay oscillator with one or more degrees of freedom of the second oscillator.

18. The thermodynamic relay gadget of claim 17, wherein the one or more degrees of freedom comprise one or more of:
a position degree of freedom;
a momentum degree of freedom; or
a force degree of freedom.

19. The thermodynamic relay gadget of claim 16, wherein the first set of one or more pulses comprises one or more time-dependent pulses given by:
$${λ}_{A} ( t ) = {λ}_{A} ( σ ( {k}_{A} ( t - {t}_{1} ) ) - σ ( {k}_{A} ( t - {t}_{2} ) ) ) ,$$
where σ(t) is a sigmoid function given by:
$$σ ( t ) = \frac{1}{1 + {e}^{- t}} .$$

20. The thermodynamic relay gadget of claim 16, further comprising:
a bias oscillator,
wherein the controller is further configured to:
cause a second set of one or more pulses to be emitted, wherein the second set of pulses couple the relay oscillator to the bias oscillator, and wherein the second set of pulses are caused to be emitted after the first set of pulses and before the other set of pulses.

21. The thermodynamic relay gadget of claim 20, wherein the second set of one or more pulses comprises one or more time-dependent pulses given by:
$${λ}_{B} ( t ) = {λ}_{B} σ ( {k}_{B} ( t - {t}_{1}^{( B )} ) ) + {λ}_{0}^{( B )} ,$$
where σ(t) is a sigmoid function given by:
$$σ ( t ) = \frac{1}{1 + {e}^{- t}} .$$

22. The thermodynamic relay gadget of claim 16, wherein the other set of one or more pulses comprises one or more time-dependent pulses given by:
$${λ}_{X} ( t ) = {λ}_{X} σ ( {k}_{X} ( t - {t}_{1}^{( X )} ) ) + {λ}_{0}^{( X )} ,$$
where σ(t) is a sigmoid function given by:
$$σ ( t ) = \frac{1}{1 + {e}^{- t}} .$$

23. The thermodynamic relay gadget of claim 16, wherein a product of mass and frequency squared of the relay oscillator is greater than a corresponding mass and frequency squared of the second oscillator, when the relay oscillator is coupled to the second oscillator.

24. A method comprising:
coupling a relay oscillator to an output oscillator;
adjusting a frequency or mass of the relay oscillator, while holding thermodynamic information acquired from the output oscillator in the relay oscillator; and
coupling the relay oscillator to an input oscillator.

25. The method of claim 24, further comprising:
coupling the relay oscillator to a bias oscillator, wherein said coupling to the bias oscillator is performed after said coupling the relay oscillator to the output oscillator and before said coupling the relay oscillator to the input oscillator.

26. The method of claim 24, wherein said coupling the relay oscillator to the output oscillator transfers analog thermodynamic information to the relay oscillator, and wherein said coupling the relay oscillator to the input oscillator transfers the analog thermodynamic information to the input oscillator.

27. The method of claim 24, wherein said coupling the relay oscillator to the output oscillator, and said coupling the relay oscillator to the input operator are repeated for a plurality of output oscillators, wherein the method implements conditional sampling of one or more energy-based models comprising the output oscillators.

28. The method of claim 24, further comprising:
storing state information received from the output oscillator in the relay oscillator prior to coupling the relay oscillator to the input oscillator.

29. The method of claim 24, wherein said coupling the relay oscillator to the output oscillator, and said coupling the relay oscillator to the input operator implement a network connection between components of a thermodynamic computing system.

30. A controller, comprising:
processing circuitry configured to:
cause a first set of one or more pulses to be emitted to couple a relay oscillator to an output oscillator;
cause one or more control signals to be emitted to increase a mass of the relay oscillator or to tune a frequency of the relay oscillator; and
cause another set of one or more pulses to be emitted to couple the relay oscillator to an input oscillator.

31. The controller of claim 30, further comprising processing circuitry configured to:
cause a second set of one or more pulses to be emitted, between the first set of pulses and the other set of pulses, wherein the second set of one or more pulses couple the relay oscillator to a bias oscillator.

32. The controller of claim 30, wherein the controller is fabricated as an on-chip controller of a thermodynamic chip.

33. The controller of claim 32, wherein the controller is pre-programmed to emit the first set of pulses, the other set of pulses, and issue the one or more control signals in a sequence that implements analog information transfer between the output oscillator and the input oscillator.
